(19) United States
(12) Patent Application Publication
(10) Pub. No.: US 2026/0210869 A1
(43) Pub. Date: Jul. 23, 2026

(54) DEFECT INSPECTING DEVICE

(71) Applicant: HITACHI HIGH-TECH CORPORATION, Minato-ku, Tokyo (JP)

(72) Inventors: Toshifumi HONDA, Tokyo (JP); Takanori KONDO, Tokyo (JP); Nobuhiro OBARA, Tokyo (JP); Shogo IGUCHI, Tokyo (JP)

(21) Appl. No.: 19/140,178

(22) PCT Filed: Dec. 23, 2022
(86) PCT No.: PCT/JP2022/047784

§ 371 Date: Jun. 17, 2025

(51) Int. Cl. G01N 21/88; G01N 21/95; G01N 21/956

(52) U.S. Cl. CPC G01N 21/8806; G01N 21/9501; G01N 21/956

(57) ABSTRACT

Provided is a defect inspecting device that analyzes a defect determination script by using a predetermined region of an input and output buffer as an input port for feature data of a defect candidate and an output port for evaluation data, configures a script data structure including a plurality of calculation data structures in which a data input unit of the input and output buffer, an instruction using data input to the data input unit, and a data output unit of the input and output buffer that stores execution data of the instruction are associated with one another, detects the defect candidate based on a detection signal output from a scattered light detection system, calculates feature data of the defect candidate based on the detection signal and inputs the feature data to the input port, calculates the evaluation data by sequentially executing, for each of the calculation data structures, processing of executing an instruction associated in the calculation data structure and storing an execution result in the data output unit, by using data of the data input unit associated in the calculation data structure, and determines whether the defect candidate is a defect based on the evaluation data output from the output port.

### TECHNICAL FIELD

The present invention relates to a defect inspecting device that inspects a sample surface and outputs a position, a type, a size, and the like of a defect.

### BACKGROUND ART

In order to improve a yield of a product such as a semiconductor substrate and a thin film substrate manufactured in a manufacturing line, the semiconductor substrate, the thin film substrate, and the like are used as a sample, and a defect on a sample surface is inspected. As a defect inspecting device used in such an inspection, there is a defect inspecting device that simultaneously detects scattered light from a sample surface using a plurality of sensors at different positions and acquires detailed data on a position, a shape, a size, and the like of a defect (see PTL 1 and the like).

### CITATION LIST

### Patent Literature

PTL 1: JP2011-013058A

### SUMMARY OF INVENTION

### Technical Problem

For example, various solutions used in a semiconductor manufacturing process may contain extremely small foreign substances of 15 nm or less. In recent years, a defect inspecting device is required to have performance of detecting such an extremely minute defect. In the defect inspecting device disclosed in PTL 1, scattered light from an illumination spot is simultaneously detected by a plurality of detection systems having different directions relative to the illumination spot, thereby obtaining a large amount of data on a defect.

A detection signal detected in an inspection process includes a signal related to a nuisance that is not desired to be detected in addition to a signal related to an important defect to be detected. For example, in an inspection process for dust generation inspection of a manufacturing device, an important defect is a foreign substance, and a polishing scratch present on a wafer before being placed into the manufacturing device is a nuisance. On the other hand, in an inspection process after a polishing process, a polishing scratch is an important defect. A foreign substance detected in this process may be removed by cleaning the wafer or the like, and often becomes a nuisance that does not need to be detected. In order to make it easy to grasp an occurrence situation of an important defect, it is important to prevent the detection of a nuisance and distinguish a nuisance from a detected defect candidate.

Further, in the detection of a minute important defect of 15 nm or less, roughness scattered light generated by minute unevenness of a sample surface may be an obstacle, in addition to the nuisance. A distribution of the roughness scattered light obtained by applying illumination light to a mirror wafer whose surface was polished is substantially constant regardless of a position on the wafer. However, in a wafer in which single crystal silicon is formed on a surface of a polished wafer such as an epitaxial wafer, a distribution of roughness scattered light changes due to the influence of a crystal orientation. In this manner, a scattering direction of the roughness scattered light varies depending on a wafer to be inspected. In the case of a mirror wafer, an inspection may be performed by rotating the mirror wafer. In this case, a scattering direction dynamically changes due to the rotation of the mirror wafer during the inspection.

As described above, an important defect varies depending on an inspection target, and a state of noises that hinder a high-sensitivity inspection also varies depending on the inspection target. Under such circumstances, when a defect determination condition is set, it may be necessary to determine detection sensitivity of an important defect and a nuisance and an inspection algorithm for classifying the important defect and the nuisance by trial and error while inspecting an inspection target and viewing a result.

However, in reality, an inspection algorithm is incorporated in a data processing unit of a defect inspecting device, and in a stage of setting a defect determination condition, it is only possible to adjust a sensitivity threshold. It is difficult to accurately set in advance a complicated algorithm corresponding to a scattered light distribution of an important defect and a nuisance and a distribution of roughness scattered light, which are clarified only after an actual inspection. It is possible to reduce a sensitivity threshold to detect a large amount of detection signals including nuisance detection signals, and it is possible to process the large amount of detection signals offline, but in this case, it takes time to obtain an inspection result. In an inspection process of inspecting several tens of wafers per hour by one defect inspecting device, it is substantially difficult to constantly perform such offline processing.

An object of the invention is to provide a defect inspecting device capable of flexibly adjusting a defect determination condition and detecting an important defect at high speed.

### Solution to Problem

In order to achieve the above object, the invention provides a defect inspecting device. The defect inspecting device includes: a scattered light illumination system configured to form an illumination spot on a sample surface; a scattered light detection system configured to detect light from the illumination spot; a signal processing device configured to process a detection signal output from the scattered light detection system; and a monitor configured to display an output of the signal processing device. The signal processing device includes a defect feature evaluation instruction analysis unit configured to analyze a defect determination script describing data processing related to evaluation of feature data by using a predetermined region of an input and output buffer, which is a specific memory area, as an input port for inputting the feature data based on the detection signal and an output port for outputting evaluation data of a defect, configure, as a calculation data structure, a data structure having a structure in which a data input unit of the input and output buffer, an instruction using data input to the data input unit, and a data output unit of the input and output buffer that stores execution data of the instruction are associated with one another, and configure a script data structure including a plurality of the calculation data structures, a defect candidate detection unit configured to detect a defect candidate based on a detection signal output from the scattered light detection system, a feature calculation unit configured to calculate feature data of the defect candidate based on the detection signal and input the calculated feature data to the input port, a feature evaluation unit configured to calculate the evaluation data by sequentially executing, for each of the calculation data structures, processing of executing an instruction associated in the calculation data structure and storing an execution result in the data output unit, by using data of the data input unit associated in the calculation data structure, and a determination unit configured to determine whether the defect candidate is a defect based on the evaluation data output from the output port.

### Advantageous Effects of Invention

According to the invention, a defect determination condition can be flexibly adjusted, and an important defect can be detected at high speed.

### BRIEF DESCRIPTION OF DRAWINGS

FIG. 1 is a schematic diagram showing a configuration example of a defect inspecting device according to a first embodiment of the invention.

FIG. 2 is a schematic diagram showing an example of a scanning trajectory on a sample scanned by a scanning device provided in the defect inspecting device according to the first embodiment of the invention.

FIG. 3 is a schematic diagram showing another example of the scanning trajectory on the sample scanned by the scanning device provided in the defect inspecting device according to the first embodiment of the invention.

FIG. 4 is a schematic diagram showing an extracted attenuator provided in the defect inspecting device according to the first embodiment of the invention.

FIG. 5 is a diagram schematically showing a positional relationship between an illumination intensity distribution shape and an optical axis of illumination light guided to a sample surface from an oblique direction by a scattered light illumination system provided in the defect inspecting device according to the first embodiment of the invention in a cross section obtained by cutting a sample at an incident surface of the illumination light incident on the sample.

FIG. 6 is a diagram schematically showing a positional relationship between an illumination intensity distribution shape and an optical axis of illumination light guided to the sample surface from an oblique direction by the scattered light illumination system provided in the defect inspecting device according to the first embodiment of the invention in a cross section obtained by cutting a sample along a plane that is orthogonal to an incident surface of the illumination light incident on the sample and includes a normal line of the sample surface.

FIG. 7 is a top view showing openings through which a scattered light detection system provided in the defect inspecting device according to the first embodiment of the invention collects scattered light.

FIG. 8 is a configuration diagram showing the scattered light detection system that is provided in the defect inspecting device according to the first embodiment of the invention and that causes light to be incident on the sample from a normal line direction and focuses scattered light from the sample surface.

FIG. 9 is a top view of FIG. 8.

FIG. 10 is a top view showing a light intensity distribution of scattered light generated by performing oblique incidence illumination on a minute defect.

FIG. 11 is a top view showing a light intensity distribution of scattered light generated by performing oblique incidence illumination on a scratch defect.

FIG. 12 is a top view showing a light intensity distribution of roughness scattered light from the sample surface generated by performing oblique incidence illumination on the sample surface.

FIG. 13 is a diagram showing a crystal orientation of an upper surface of an epitaxial wafer.

FIG. 14 is a top view showing a light intensity distribution of roughness scattered light from the sample surface generated by performing oblique incidence illumination on the epitaxial wafer in FIG. 13.

FIG. 15 is a diagram showing a wafer distribution of a light intensity of roughness scattered light detected by a specific sensor while rotating the epitaxial wafer in FIG. 13.

FIG. 16 is a diagram showing a wafer distribution of a light intensity of roughness scattered light detected by a sensor different from that in FIG. 15 while rotating the epitaxial wafer in FIG. 13.

FIG. 17 is a part of a block diagram showing processing of a signal processing device provided in the defect inspecting device according the first embodiment of the invention.

FIG. 18 is a conceptual diagram showing defect type distinguish of the signal processing device provided in the defect inspecting device according to the first embodiment of the invention.

FIG. 19 is a diagram showing an example of ports and scripts used in a feature evaluation unit of the signal processing device provided in the defect inspecting device according to the first embodiment of the invention.

FIG. 20 is a diagram showing an example of a data structure for achieving an increase in speed of an instruction described in a script in the feature evaluation unit of the signal processing device provided in the defect inspecting device according to the first embodiment of the invention.

FIG. 21 is a view showing a concept of applying a different script for each region of the sample in the feature evaluation unit of the signal processing device provided in the defect inspecting device according to the first embodiment of the invention.

FIG. 22 is a flowchart showing an inspection procedure of the defect inspecting device according to the first embodiment of the invention.

FIG. 23 is a schematic diagram showing an interference detection system and a data processing unit provided in a defect inspecting device according to a second embodiment of the invention.

FIG. 24 is a schematic diagram showing a scattered light imaging detection unit provided in the defect inspecting device according to the second embodiment of the invention.

FIG. 25 is a flowchart showing an inspection procedure of the defect inspecting device according to the second embodiment of the invention.

FIG. 26 is a diagram showing feature data applied by a feature evaluation unit provided in the defect inspecting device according to the second embodiment of the invention.

FIG. 27 is a diagram showing an example of ports and scripts used in the feature evaluation unit of a signal processing device provided in the defect inspecting device according to the second embodiment of the invention.

FIG. 28 is a schematic diagram showing a GUI for creating a script in the defect inspecting device according to the second embodiment of the invention.

FIG. 29 is a schematic diagram showing a GUI for confirming defect detection performance by a script in the defect inspecting device according to the second embodiment of the invention.

FIG. 30 is a schematic diagram showing a signal processing device provided in a defect inspecting device according to a third embodiment of the invention.

FIG. 31 is a table showing an example of signal integration according to the third embodiment of the invention.

### DESCRIPTION OF EMBODIMENTS

Hereinafter, embodiments of the invention will be described with reference to the drawings.

In the following embodiments, a defect inspecting device to which the invention is applied is used for inspecting a defect on a surface of a sample (wafer), which is performed during a manufacturing process of, for example, a semiconductor. According to the defect inspecting device according to the embodiments, it is possible to perform, at high speed, processing of detecting a minute defect of the sample and acquiring data on the number, position, dimension, and type of the defect.

### First Embodiment

### Defect Inspecting Device

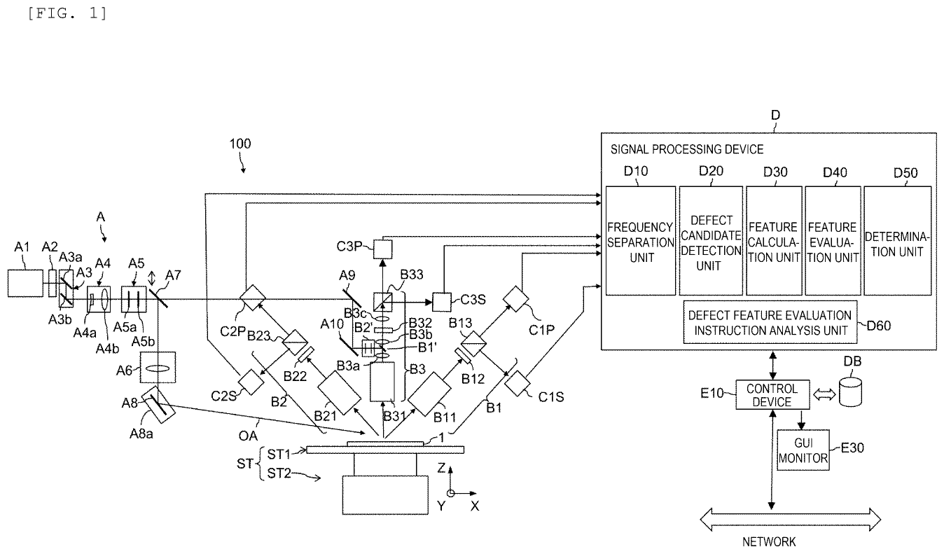

FIG. 1 is a schematic diagram showing a configuration example of a defect inspecting device according to a first embodiment of the invention. A defect inspecting device 100 according to the embodiment uses a sample 1 as an inspection target, and detects a defect such as a foreign substance or a recess on a surface of the sample 1 (hereinafter, referred to as a sample surface), particularly, a defect of a type corresponding to an inspection purpose. A circular plate-shaped semiconductor silicon wafer having a flat surface on which no pattern is formed is assumed as a representative example of the sample 1. The defect inspecting device 100 includes a stage ST, a scattered light illumination system A, a plurality of (n) scattered light detection systems B1 to Bn, a signal processing device D, a control device E10, a monitor E30, and a secondary storage device DB. The scattered light detection systems B1 to Bn include respective sensors C1P to CnP and C1S to CnS. When a sensor CiP is mentioned, the sensor CiP refers to a sensor that detects P-polarized light of the i-th scattered light detection system Bi. Similarly, when a sensor Cis is mentioned, the sensor Cis refers to a sensor that detects S-polarized light of the i-th scattered light detection system Bi.

### Stage

The stage ST includes a sample stage ST1 and a scanning device ST2. The sample stage ST1 is a stage that supports the sample 1. The scanning device ST2 is a device that drives the sample stage ST1 to change a relative position between the sample 1 and the scattered light illumination system A. Although detailed illustration is omitted, the scanning device ST2 includes a translation stage, a rotation stage, and a Z stage. Specifically, the rotation stage is supported by the translation stage via the Z stage, and the sample stage ST1 is supported by the rotation stage. The translation stage is translated in a horizontal direction together with the rotation stage, and the rotation stage rotates about an axis extending vertically. The Z stage functions to adjust a height of a sample surface.

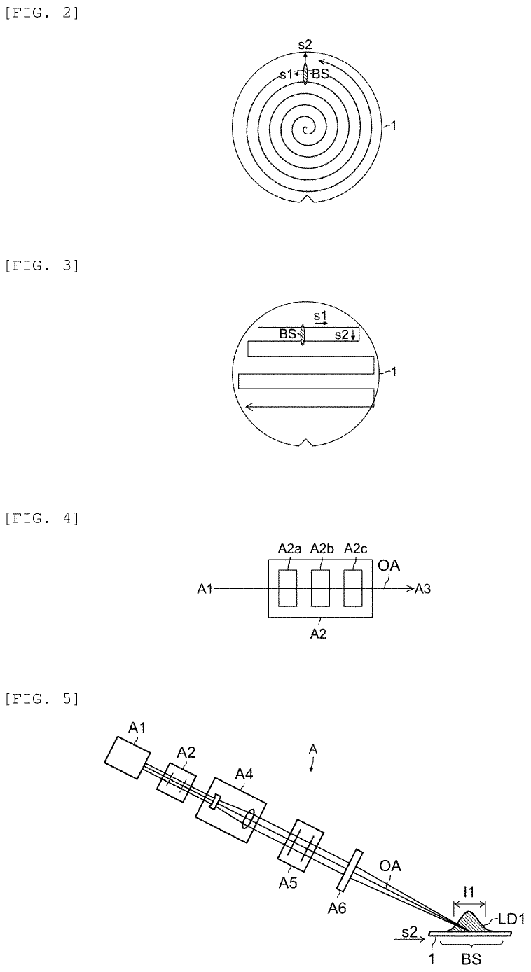

FIG. 2 is a schematic diagram showing a scanning trajectory on the sample 1 scanned by the scanning device ST2. As will be described later, an illumination spot BS formed on the sample surface by illumination light emitted from the scattered light illumination system A has an illumination intensity distribution that is long in one direction as shown in FIG. 2. A major axis direction of the illumination spot BS is defined as s2, and a direction intersecting the major axis (for example, a minor axis direction orthogonal to the major axis) is defined as s1. The sample 1 is rotated along with the rotation of the rotation stage, scanning is performed on the sample surface using the illumination spot BS in the s1 direction, the sample 1 is moved in a horizontal direction along with the translation of the translation stage, and scanning is performed on the sample surface using the illumination spot BS in the s2 direction. When the sample 1 is moved while being rotated by an operation of the scanning device ST2, as shown in FIG. 2, the illumination spot BS moves presenting a spiral trajectory from a center to an outer edge of the sample 1, and the entire surface of the sample 1 is scanned. The illumination spot BS moves in the s2 direction by a distance equal to or less than a length of the illumination spot BS in the s2 direction during one rotation of the sample 1.

A scanning device having a configuration in which another translation stage whose movement axis extends in a direction intersecting a movement axis of the translation stage in a horizontal plane is provided instead of the rotation stage can also be applied. In this case, as shown in FIG. 3, the sample surface is scanned using the illumination spot BS in a folded linear trajectory instead of the spiral trajectory. Specifically, a first translation stage performs a translational movement in the s1 direction at a constant speed, a second translation stage is driven in the s2 direction by a predetermined distance (for example, a distance equal to or less than a length of the illumination spot BS in the s2 direction), and then the first translation stage turns back and performs a translational movement in the s1 direction again. Accordingly, the entire surface of the sample 1 is scanned using the illumination spot BS by repeating linear scanning in the s1 direction and movement in the s2 direction. Compared with this scanning method, since the spiral scanning method shown in FIG. 2 does not involve a reciprocating operation, the spiral scanning method is advantageous in inspecting a sample in a short time.

### Scattered Light Illumination System

The scattered light illumination system A shown in FIG. 1 includes an optical element group for illuminating the sample 1 placed on the sample stage ST1 with desired illumination light. As shown in FIG. 1, the scattered light illumination system A includes a laser light source A1, an attenuator A2, an emitted light adjustment unit A3, a beam expander A4, a polarization control unit A5, a light condensing optical unit A6, reflection mirrors A7 to A9, and the like.

### Laser Light Source

The laser light source A1 is a unit that emits a laser beam as illumination light. When the defect inspecting device 100 detects a minute defect in the vicinity of the sample surface, a device that oscillates a high-power laser beam having an output of 2 W or more is used as the laser light source A1, the laser beam being ultraviolet or vacuum ultraviolet having a short wavelength (wavelength of 355 nm or less) that is hardly transmitted to the inside of the sample 1. A diameter of the laser beam emitted from the laser light source A1 is typically about 1 mm. When the defect inspecting device 100 detects a defect inside the sample 1, a device that oscillates a visible or infrared laser beam having a long wavelength and is easily transmitted to the inside of the sample 1 is used as the laser light source A1.

### Attenuator

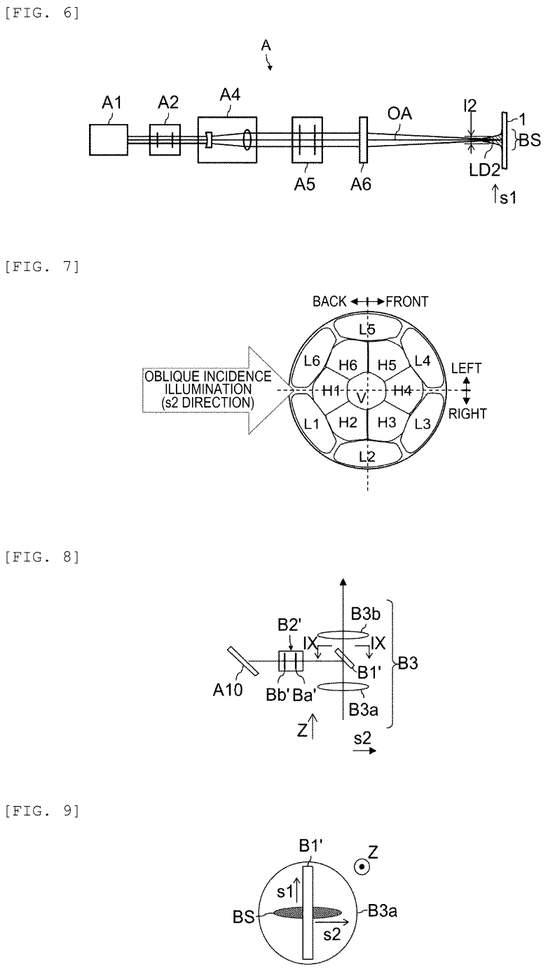

FIG. 4 is a schematic diagram showing the attenuator A2. The attenuator A2 is a unit that attenuates a light intensity of the illumination light emitted from the laser light source A1, and in the embodiment, the attenuator A2 has a configuration in which a first polarization plate A2a, a ½ wavelength plate A2b, and a second polarization plate A2c are combined. The ½ wavelength plate A2b is rotatable around an optical axis of the illumination light. The illumination light incident on the attenuator A2 is converted into linearly polarized light by the first polarization plate A2a, and then passes through the second polarization plate A2c after a polarization direction of the illumination light is adjusted to a slow axis azimuth angle of the ½ wavelength plate A2b. By the azimuth angle adjustment in the ½ wavelength plate A2b, the light intensity of the illumination light can be attenuated at any ratio. When a linear polarization degree of the illumination light incident on the attenuator A2 is sufficiently high, the first polarization plate A2a may be omitted. The attenuator A2 is not limited to the configuration shown in FIG. 4, and may be implemented by using an ND filter having a gradation density distribution, and may have a configuration capable of adjusting an attenuation effect by a combination of a plurality of ND filters having different densities.

### Emitted Light Adjustment Unit

The emitted light adjustment unit A3 shown in FIG. 1 is a unit that adjusts an angle of the optical axis of the illumination light attenuated by the attenuator A2, and the emitted light adjustment unit A3 includes a plurality of reflection mirrors A3a and A3b in the embodiment. Although the illumination light is sequentially reflected by the reflection mirrors A3a and A3b, in the embodiment, an incidence and emission surface of the illumination light onto and from the reflection mirror A3a is orthogonal to an incidence and emission surface of the illumination light onto and from the reflection mirror A3b. The incidence and emission surface is a surface having an optical axis along which light is incident on the reflection mirror and an optical axis along which light is emitted from the reflection mirror. For example, when a three-dimensional XYZ orthogonal coordinate system is defined and the illumination light is incident on the reflection mirror A3a in a +X direction, the illumination light is, for example, deflected by the reflection mirror A3a in a +Y direction and then deflected by the reflection mirror A3b in a +Z direction, which is different from the schematic diagram shown in FIG. 1. In this example, the incidence and emission surface of the illumination light onto and from the reflection mirror A3a is an XY plane, and the incidence and emission surface onto and from the reflection mirror A3b is a YZ plane. The reflection mirrors A3a and A3B are provided with mechanisms (not shown) for causing the respective reflection mirrors A3a and A3b to perform a translational movement and mechanisms (not shown) for tilting the reflection mirrors A3a and A3b. For example, the reflection mirrors A3a and A3b perform a translational movement in an incident direction or an emission direction of illumination light onto and from the reflection mirrors A3a and A3b, and are tilted around a normal line to the incidence and emission surface. Accordingly, for example, relative to an optical axis of the illumination light emitted in the +Z direction from the emitted light adjustment unit A3, an offset amount and an angle in an XZ plane and an offset amount and an angle in a YZ plane can be independently adjusted. Although a configuration using two reflection mirrors A3a and A3b is shown in this example, a configuration using three or more reflection mirrors may be used.

### Beam Expander

The beam expander A4 is a unit that enlarges a beam diameter of incident illumination light, and includes a plurality of lenses A4a and A4b. An example of the beam expander A4 is of a Galileo type using a concave lens as the lens A4a and a convex lens as the lens A4b. The beam expander A4 includes an interval adjustment mechanism (zoom mechanism) for the lenses A4a and A4b, and a magnification ratio of the beam diameter is changed by adjusting an interval between the lenses A4a and A4b. The magnification ratio of the beam diameter adjusted by the beam expander A4 is about 5 to 10 times. In this case, when a beam diameter of the illumination light emitted from the laser light source A1 is 1 mm, a beam system of the illumination light is enlarged to about 5 mm to 10 mm. When the illumination light incident on the beam expander A4 is not a parallel beam, the illumination light can be collimated (quasi-collimated) together with the beam diameter by adjusting the interval between the lenses A4a and A4b. Alternatively, the beam may be collimated by a collimating lens provided upstream of the beam expander A4 and separately from the beam expander A4.

The beam expander A4 is provided on a translation stage having two or more axes (two or more degrees of freedom), and a position of the beam expander A4 can be adjusted such that a center of the beam expander A4 coincides with a center of the incident illumination light. Further, the beam expander A4 is also provided with a tilt angle adjustment function having two or more axes (two or more degrees of freedom) such that an optical axis of light transmitting in the beam expander A4 coincides with an optical axis of the incident illumination light.

### Polarization Control Unit

The polarization control unit A5 is an optical system that controls a polarization state of the illumination light, and includes a ½ wavelength plate A5a and a ¼ wavelength plate A5b. For example, when oblique incidence illumination is performed by placing the reflection mirror A7 on an optical path, which will be described later, an amount of scattered light from a defect on the sample surface increases by setting the illumination light to be P-polarized light by the polarization control unit A5, as compared with polarized light other than the P-polarized light. When scattered light (referred to as haze) from minute unevenness of the sample surface hinders detection of a minute defect, the illumination light is set to S-polarized light, so that the haze can be reduced as compared with polarized light other than the S-polarized light. The polarization control unit A5 can also set the illumination light to be circularly polarized light or to be 45° polarized light between the P-polarized light and S-polarized light.

### Reflection Mirror

As shown in FIG. 1, the reflection mirror A7 can switch an incident path of the illumination light onto the sample 1 by causing the reflection mirror A7 to perform a parallel movement in an arrow direction by a drive mechanism (not shown) and entering and leaving the optical path of the illumination light that travels toward the sample 1. By inserting the reflection mirror A7 into the optical path, the illumination light emitted from the polarization control unit A5 as described above is reflected by the reflection mirror A7 and then is obliquely incident on the sample 1 through the light condensing optical unit A6 and the reflection mirror A8. On the other hand, when the reflection mirror A7 is moved out of the optical path, the illumination light emitted from the polarization control unit A5 is perpendicularly incident on the sample 1 via the reflection mirrors A9 and A10, a polarization control unit B2′, a reflection mirror B1′, and a scattered light detection system B3. Similar to the polarization control unit A5, the polarization control unit B2′ includes a ½ wavelength plate Ba′ and a ¼ wavelength plate Bb′.

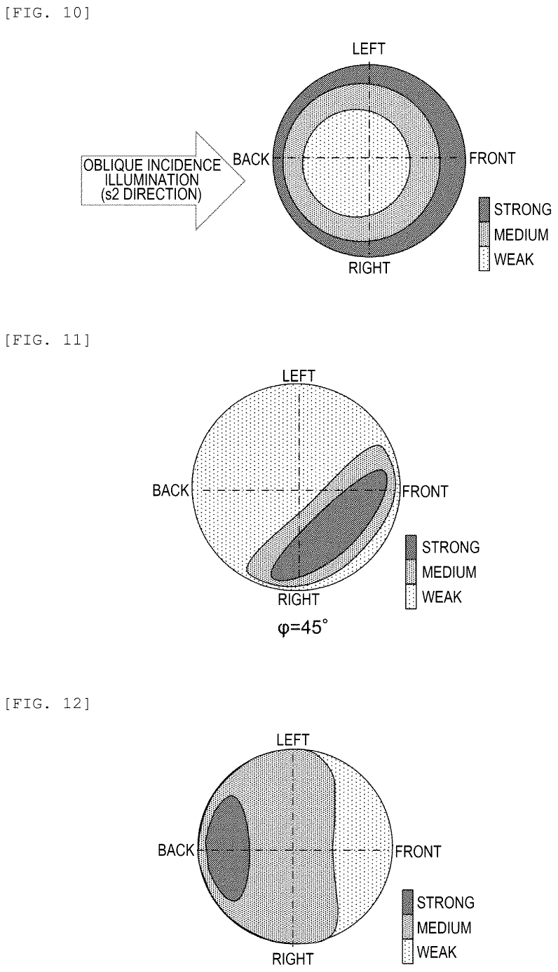

FIGS. 5 and 6 are schematic diagrams showing a positional relationship between the optical axis of the illumination light guided to the sample surface from an oblique direction by the scattered light illumination system A and an illumination intensity distribution shape. FIG. 5 schematically shows a cross-section of the sample 1 cut along an incident surface of the illumination light incident on the sample 1. FIG. 6 schematically shows a cross-section of the sample 1 cut along a surface that is orthogonal to the incident surface of the illumination light incident on the sample 1 and that has a normal line of the sample surface. The incident surface is a plane including an optical axis OA of the illumination light incident on the sample 1 and the normal line of the sample surface. In FIGS. 5 and 6, a part of the scattered light illumination system A is extracted and shown. For example, the emitted light adjustment unit A3 and the reflection mirrors A7 and A8 are not shown.

When the reflection mirror A7 is inserted into the optical path, the illumination light emitted from the laser light source A1 is condensed by the light condensing optical unit A6, is reflected by the reflection mirror A8, and is obliquely incident on the sample 1. In this manner, the scattered light illumination system A is configured such that the illumination light can be incident on the sample 1 from a direction tilted relative to the normal line of the sample surface. In oblique incidence illumination, a light intensity is adjusted by the attenuator A2, a beam diameter is adjusted by the beam expander A4, and polarization is adjusted by the polarization control unit A5, and an illumination intensity distribution is made uniform on an incident surface. As in illumination intensity distribution (illumination profile) LD1 shown in FIG. 5, an illumination spot formed on the sample 1 has a Gaussian light intensity distribution in the s2 direction, and a length of a beam width 11 defined by 13.5% of a peak is, for example, about 25 μm to 4 mm.

On a surface orthogonal to the incident surface and the sample surface, an illumination spot has a light intensity distribution in which an intensity in the periphery is weak as compared with an intensity at a center of the optical axis OA as in an illumination intensity distribution (illumination profile) LD2 shown in FIG. 6. Specifically, the light intensity distribution is, for example, a Gaussian distribution reflecting an intensity distribution of light incident on the light condensing optical unit A6 or an intensity distribution similar to a first-type first-order Bessel function or a sinc function reflecting an opening shape of the light condensing optical unit A6. A length 12 of an illumination intensity distribution on a surface orthogonal to the incident surface and the sample surface is set to be shorter than the beam width 11 shown in FIG. 5, and is set to, for example, about 1.0 μm to 20 μm in order to reduce a haze generated from the sample surface. The length 12 of the illumination intensity distribution is a length of a region having an illumination intensity of 13.5% or more of a maximum illumination intensity on the surface orthogonal to the incident surface and the sample surface.

An incident angle on the sample 1 (a tilt angle of an incidence optical axis relative to the normal line of the sample surface) i in the oblique incidence illumination is adjusted to an angle suitable for detection of a minute defect at positions and angles of the reflection mirrors A7 and A8. The angle of the reflection mirror A8 is adjusted by an adjustment mechanism A8a. For example, the larger the incident angle of the illumination light on the sample 1 (the smaller an illumination elevation angle that is an angle formed by the sample surface and the incident optical axis) is, the weaker the haze that becomes noises for the scattered light from a minute foreign substance on the sample surface is, making it suitable for detecting a minute defect. From the viewpoint of reducing the influence of the haze on the detection of the minute defect, the incident angle of the illumination light is preferably set to, for example, 75 degrees or more (elevation angle of 15 degrees or less). On the other hand, in the oblique incidence illumination, since an absolute amount of scattered light from a minute foreign substance increases as an illumination incident angle decreases, it is preferable to set the incident angle of the illumination light to, for example, 60 degrees or more and 75 degrees or less (that is, the elevation angle of 15 degrees or more and 30 degrees or less) from the viewpoint of increasing an amount of scattered light from a defect.

### Scattered Light Detection System

The scattered light detection systems B1 to Bn are units that collect and detect scattered light from the illumination spot BS on the sample surface, and include a plurality of optical elements including a condenser lens (objective lens). This optical system detects scattered light from the sample surface to perform laser scattering detection. The n of the scattered light detection system Bn indicates the number of scattered light detection systems, and a case in which the defect inspecting device 100 according to the embodiment includes 13 scattered light detection system will be described as an example (n=13). The i-th scattered light detection system Bi includes an objective lens Bi1, a ½ wavelength plate Bi2 that can be rotated about an optical axis of the scattered light detection system Bi by a rotation mechanism (not shown), and a polarization beam splitter Bi3. A polarization direction is controlled by rotating the ½ wavelength plate Bi2, and light is split into two desired light beams having polarization directions orthogonal to each other by the polarization beam splitter Bi3. P-polarized light traveling straight through the polarization beam splitter Bi3 is detected by the sensor CiP, and S-polarized light reflected by the polarization beam splitter Bi3 is detected by the sensor Cis.

FIG. 7 is a diagram showing openings where the scattered light detection systems B1 to B13 collect scattered light as viewed from above and that correspond to an arrangement of objective lenses of the scattered light detection systems B1 to B13. In the following description, with reference to an incident direction of the oblique incidence illumination on the sample 1, a traveling direction (right direction in FIG. 7) of incident light with respect to the illumination spot BS on the sample surface when viewed from above is referred to as a front side, and an opposite direction (left direction in FIG. 7) is referred to as a rear side. Accordingly, a lower side in FIG. 7 is a right side and an upper side is a left side with respect to the illumination spot BS.

The objective lenses of the scattered light detection systems B1 to B13 are arranged along an upper half hemispherical surface of a sphere (celestial sphere) centered on the illumination spot BS on the sample 1. This hemispherical surface is divided into 13 regions of openings L1 to L6, H1 to H6, and V, and the scattered light detection systems B1 to B13 collect and condense scattered light at the corresponding openings.

The opening V is a region overlapping the zenith and is located directly above the illumination spot BS formed on the sample surface.

The openings L1 to L6 are regions obtained by equally dividing an annular region surrounding 360 degrees around the illumination spot BS at a low angle and are arranged in an order of the openings L1, L2, L3, L4, L5, and L6 in a counterclockwise manner from the incident direction in the oblique incidence illumination when viewed from above. Among the openings L1 to L6, the openings L1 to L3 are positioned at a right side of the illumination spot BS, the opening L1 is positioned at a right rear side, the opening L2 is positioned at a right side, and the opening L3 is positioned at a right front side of the illumination spot BS. The openings L4 to L6 are positioned at a left side of the illumination spot BS, the opening L4 is positioned at a left front side, the opening L5 is positioned at a left side, and the opening L6 is positioned at a left rear side of the illumination spot BS.

The remaining openings H1 to H6 are regions obtained by equally dividing an annular region surrounding 360 degrees around the illumination spot BS at a high angle (between the openings L1 to L6 and the opening V), and are arranged in the order of the openings H1, H2, H3, H4, H5, and H6 in a counterclockwise manner from the incident direction in the oblique incidence illumination when viewed from above. The high-angle openings H1 to H6 are shifted by 30 degrees from the low-angle openings L1 to L6 when viewed from above. Among the openings H1 to H6, the opening H1 is positioned in the rear of the illumination spot BS, and the opening H4 is positioned in front of the illumination spot BS. The openings H2 and H3 are positioned at a right side of the illumination spot BS, the opening H2 is positioned at a right rear side of the illumination spot BS, and the opening H3 is positioned at a right front side of the illumination spot BS. The openings H5 and H6 are positioned at a left side of the illumination spot BS, the opening H5 is positioned at a left front side of the illumination spot BS, and the opening H6 is positioned at a left rear side of the illumination spot BS.

In FIG. 1, scattered light incident on the scattered light detection system Bi is condensed and guided to the corresponding sensors CiP and Cis. When FIGS. 1 and 7 are compared with each other, for example, the scattered light detection system B1 in FIG. 1 can be treated as an example of an optical system that collects scattered light at the opening L4 in FIG. 7, the scattered light detection system B2 can be treated as an example of an optical system that collects scattered light at the opening L6, and the scattered light detection system B3 can be treated as an example of an optical system that collects scattered light at the opening V.

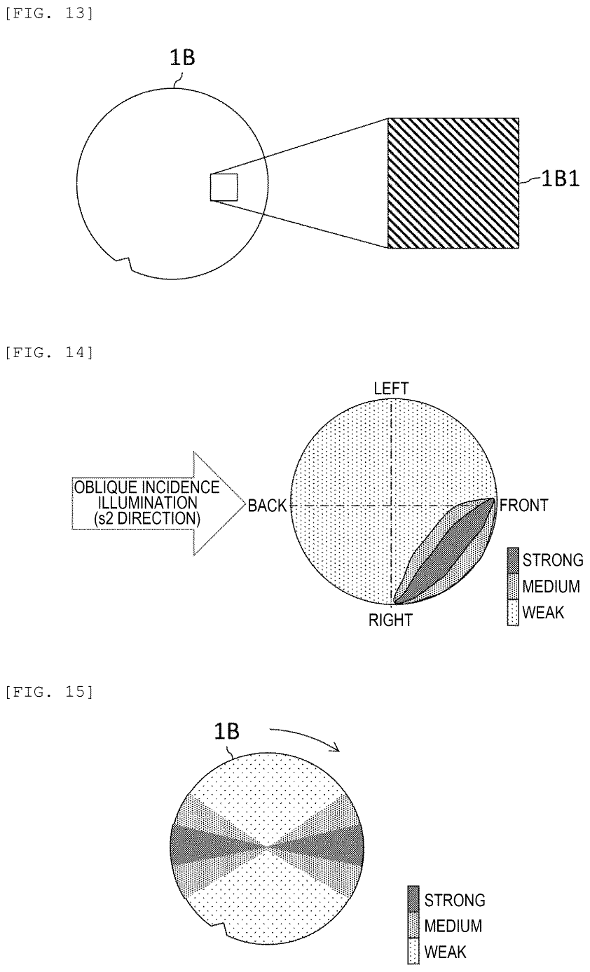

FIG. 8 is a configuration diagram showing the scattered light detection system B3 on which scattered light emitted from the sample 1 in the normal direction is incident, and FIG. 9 is a plan view of FIG. 8 as viewed from above. The scattered light detection system B3 includes a condenser lens (objective lens) B3a and an imaging lens B3b, and scattered light condensed by the condenser lens B3a is detected by sensors C3P and C3S via the imaging lens B3b, a ½ wavelength plate B32, and a polarization beam splitter B33. This point is the same for the other scattered light detection systems B1, B2, B4, and the like. The scattered light detection system B3 is different from the other scattered light detection systems in that a reflection mirror B1′ is disposed at a pupil position of the scattered light detection system B3 between the condenser lens B3a and the imaging lens B3b. As described above, in epi-illumination, the illumination light is incident on the sample 1 from a normal line direction via the reflection mirror B1′. Therefore, the condenser lens B3a of the scattered light detection system B3 also serves as a condenser lens that guides epi-illumination to the sample 1.

As described above, the illumination spot BS has a linear intensity distribution elongated in the s2 direction. As shown in FIG. 9, the reflection mirror B1′ has a shape longer than the illumination spot BS in the minor axis direction (s1 direction) of the linear illumination spot BS and shorter than the illumination spot BS in the major axis direction (s2 direction) of the illumination spot BS when viewed from the sensors C3P and C3S. The reflection mirror B1′ is disposed at a pupil position of the condenser lens B3a, directly reflected light incident on the condenser lens B3a from the sample 1 is reflected by the reflection mirror B1′, and scattered light not reflected here is guided to the imaging lens B3b.

### Sensor

The sensors C1P to CnP and C1S to CnS are single-pixel point sensors that convert the scattered light collected through the corresponding openings into electric signals and output detection signals. A photomultiplier, a silicon photomultiplier (SiPM), or the like that photoelectrically converts a weak signal at a high gain can be used as the sensors C1P to CnP and C1S to CnS. Typically, the SiPM is compact and robust against magnetic noises as compared with the photomultiplier, whereas the photomultiplier is excellent in linearity of a signal. Therefore, the SiPM and the photomultiplier may be applied at the same time. In the embodiment, the SiPM is applied as the sensors C1P to CnP, and the photomultiplier is applied as the sensors CIS to CnS. A polarization direction of light incident on the sensors CiP and Cis can be adjusted by setting a rotation angle of the ½ wavelength plate Bi2. For example, although a defect type required to be detected with high sensitivity differs depending on an inspection process, light in a polarization direction required to be detected with high sensitivity can be guided to the sensor CiP by adjusting a rotation angle of the polarization beam splitter Bi2. Detection signals output from the sensors CIP to CnP and C1S to CnS are input to the signal processing device D as needed.

### Control Device

The control device E10 is a computer that integrally controls the defect inspecting device 100, and includes a CPU, an FPGA, a timer, and the like in addition to a ROM, a RAM, and other memories. The control device E10 is connected to the monitor E30 and the signal processing device D in a wired or wireless manner. Various input devices such as a keyboard, a mouse, and a touch panel are appropriately connected to the control device E10 as devices for a user to input various operations. Inspection conditions and the like received from the input devices according to an encoder of the rotation stage and the translation stage and an operation of an operator are input to the control device E10. The inspection conditions include, for example, a type, a magnitude, a shape, a material, an illumination condition, and a defect determination condition of the sample 1. Further, the control device E10 outputs an instruction signal for instructing an operation of the stage ST, the scattered light illumination system A, and the like according to the inspection conditions, and outputs coordinate data of the illumination spot BS synchronized with a detection signal of a defect to the signal processing device D. The control device E10 also displays an output of the signal processing device D (such as a defect inspection result of the sample 1) on the monitor E30. As shown in FIG. 1, the control device E10 is connected to a network, and can input inspection condition data and output an inspection result via the network. It is also possible to output the inspection result to an inspection and measurement device connected to the network. For example, a defect review-scanning electron microscope (DR-SEM), which is an electron microscope for defect inspection, is connected to the control device E10. In this case, an inspection result can be transmitted from the control device E10 as data of a defect inspection result from the DR-SEM, a defect can be observed by the DR-SEM, a type of the defect can be determined, and then a result can be input to the control device E10.

### Example of Scattered Light Distribution

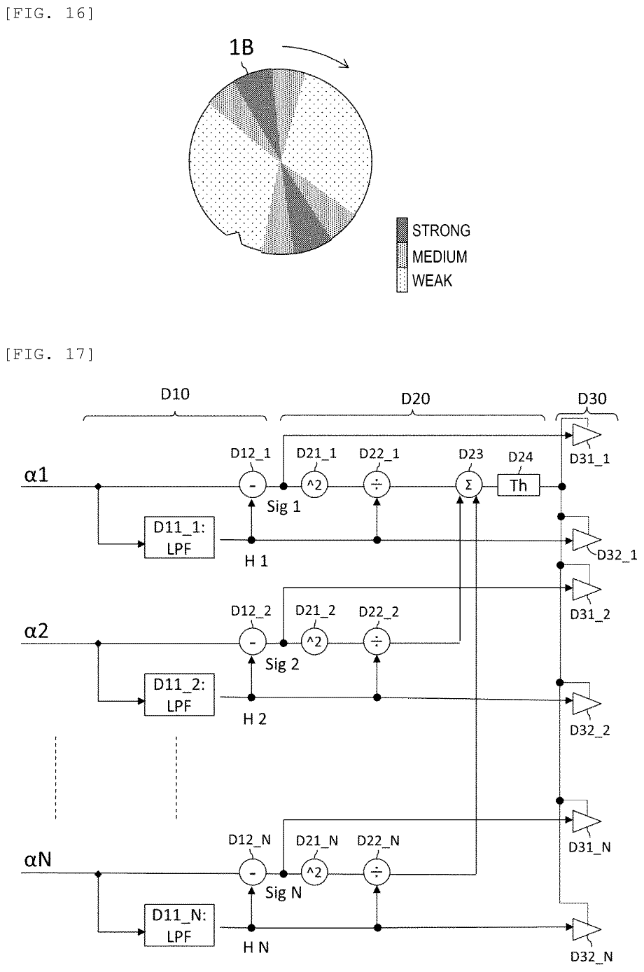

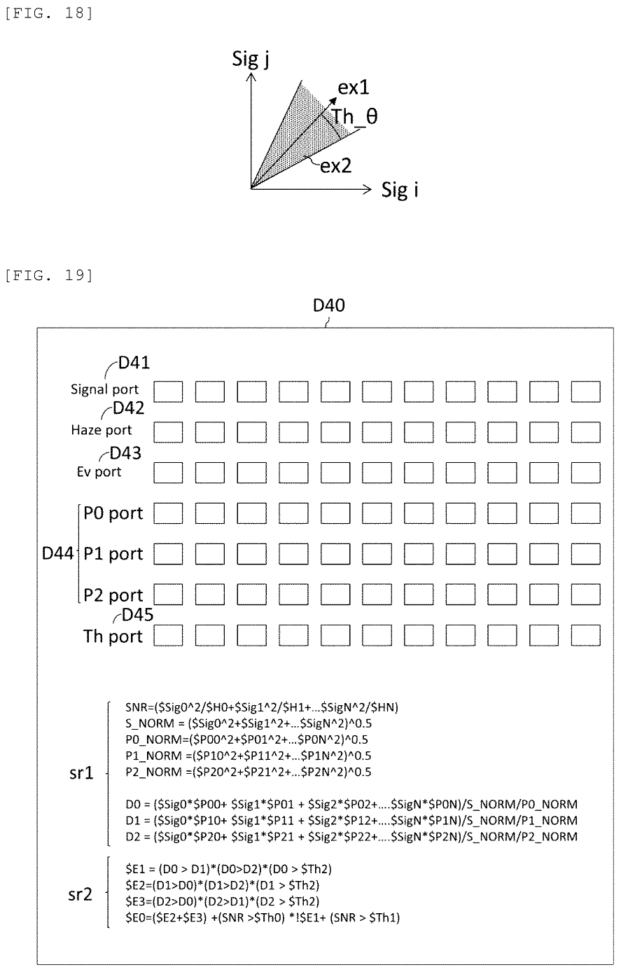

Here, FIG. 10 shows a distribution of scattered light from a foreign substance on the sample surface when oblique incidence illumination is performed from a left side of FIG. 10 as viewed from a wafer normal direction. The light scattered in a direction of direct reflection of the illumination is referred to as forward scattering, and the light scattered in an incident direction of the illumination is referred to as backward scattering, which are described as front and back in the drawings. Light scattered to the left and right with respect to the incidence of illumination is referred to as left side scattering and right side scattering, and are described as left and right in the drawing. The scattering from the foreign substance on the sample surface is isotropic, and a high-angle amount of the scattered light is less than a low-angle amount of the scattered light. FIG. 11 similarly shows a distribution of scattered light from a scratch on the sample surface having an angle of 45° relative to an incident direction of illumination. Different from the foreign substance, scattered light from the scratch having an angle of 45° has a large amount of light condensed at an opening on the front right side, and a large amount of scattered light is obtained even at a high angle as compared with FIG. 10. From the examples in FIGS. 10 and 11, it can be seen that the scattered light distribution changes depending on a defect shape.

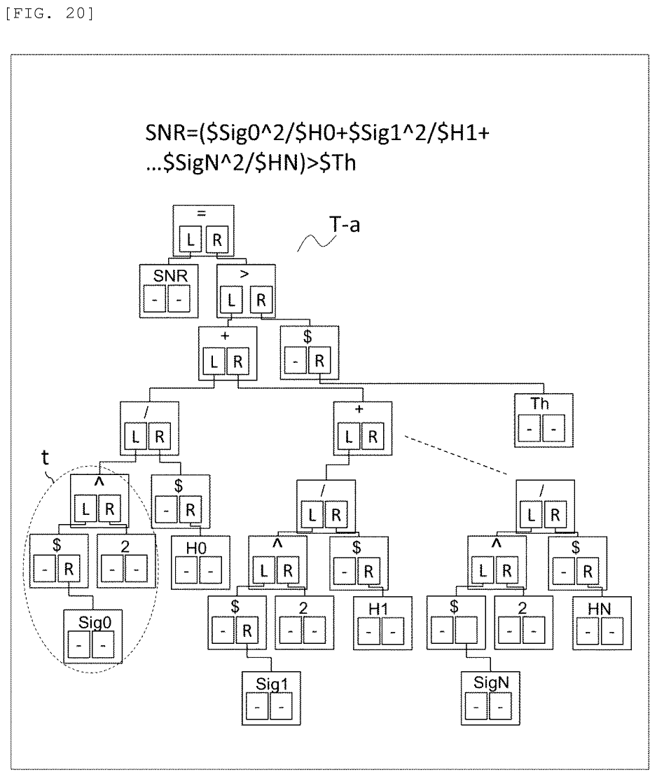

FIG. 12 shows a distribution of roughness scattered light from freely selected coordinates on the sample surface when oblique incidence illumination is performed in a similar manner on a polished wafer whose surface was polished as a sample. The roughness scattered light causes shot noises in a sensor and deteriorates defect detection sensitivity. As shown in FIG. 12, since the roughness scattered light has strong backward scattering and weak forward scattering, good sensitivity can be obtained in a front sensor or a side sensor. FIG. 13 is a schematic view showing a surface structure of an epitaxial wafer. A sample 1B which is an epitaxial wafer is produced by vapor-growing a silicon single crystal on a surface of a polished wafer. At this time, roughness having directionality is generated on a surface as shown in an enlarged section 1B1 due to an orientation of the silicon single crystal on the surface. When oblique incidence illumination is performed on the sample 1B from a left side, roughness scattered light depending on directionality of the roughness is generated as shown in FIG. 14.

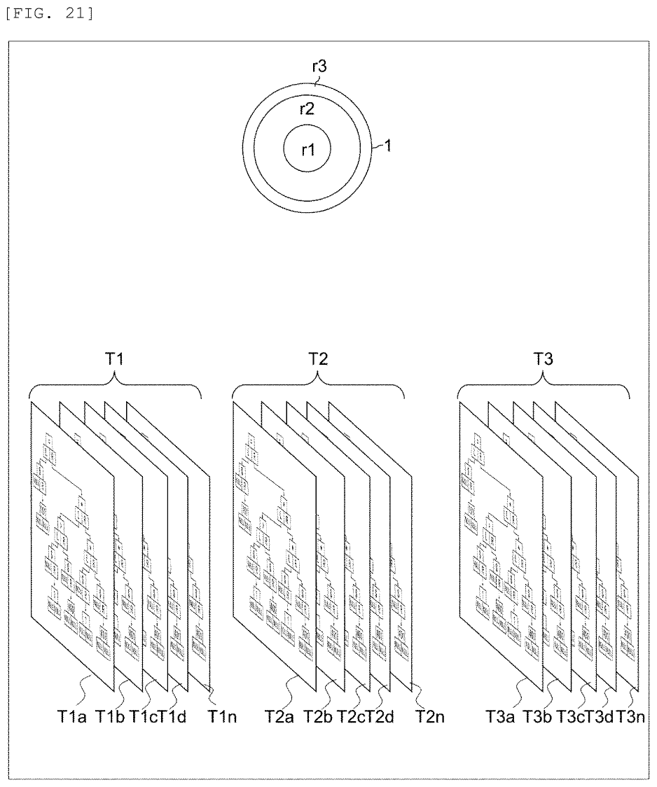

When the sample 1B is rotated and scanned by an operation of the scanning device ST2 as shown in FIG. 2, a direction of the surface roughness of the sample 1B with respect to the oblique incidence illumination changes, and thus a scattered light distribution in a far field changes. FIG. 15 is a distribution diagram showing roughness of the sample surface obtained by the scattered light detection system corresponding to the opening L3 shown in FIG. 7. Different from the polished wafer, in the case of the epitaxial wafer, an intensity of the roughness scattered light changes with the rotation of the sample. FIG. 16 is a distribution diagram showing roughness of the sample surface obtained by the scattered light detection system corresponding to the opening L4. Since the scattered light distribution changes depending on a direction of the roughness of the sample surface, an intensity of the scattered light from the sample 1B changes depending on an opening position.

When the sample is a polished wafer, a sensitivity difference depending on the opening position is substantially constant. For example, as shown in FIG. 10 as described above, for a foreign substance on the sample surface, the same amount of scattered light from a defect is obtained substantially isotropically at the low-angle openings L1 to L6. In the distribution of the roughness scattered light in FIG. 12, since a light amount of the forward scattering is low, even when the wafer is rotated and inspected, a foreign substance on the sample surface can be detected with good sensitivity at all times by the sensors corresponding to the opening L3 and the opening L4.

On the other hand, in a case where the roughness of the sample surface has directionality as in the epitaxial wafer, an intensity of the roughness scattered light changes individually at each opening position with the rotation of the wafer, and a sensor that can obtain good sensitivity changes from moment to moment accompanying with an angle change of the sample relative to the oblique incidence illumination.

### Signal Processing Device

The signal processing device D executes defect determination processing based on the scattered light distributions in a far field as shown in FIGS. 10 to 16. The signal processing device D is a computer that processes detection signals received from the sensors C1P to CnP and C1S to CnS, and similar to the control device E10, the signal processing device D includes a CPU, an FPGA, a timer, and the like, in addition to a ROM, a RAM, and other memories. For example, the signal processing device D is assumed to be implemented by a single computer that forms a unit with a device main body (a stage, a scattered light illumination system, a scattered light detection system, and the like) of the defect inspecting device 100, and in addition, the signal processing device D may be implemented by a plurality of computers. In this case, a server may be used as one of the plurality of computers, and the server may also be included in components of the defect inspecting device 100. For example, a configuration may be adopted in which a computer attached to the device main body acquires a detection signal of a defect from the device main body, processes detection data as necessary, and transmits the processed detection data to a server, and the server performs processing such as defect detection and classification.

In the embodiment, the signal processing device D includes a frequency separation unit D10, a defect candidate detection unit D20, a feature calculation unit D30, a feature evaluation unit D40, a determination unit D50, and a defect feature evaluation instruction analysis unit D60. The frequency separation unit D10, the defect candidate detection unit D20, the feature calculation unit D30, the feature evaluation unit D40, the determination unit D50, and the defect feature evaluation instruction analysis unit D60 may be virtually implemented by software or may be implemented by hardware such as an electronic circuit. A part (particularly, an upstream process) of the frequency separation unit D10 and the like may be implemented by an FPGA or a DSP. Some or all functions of the frequency separation unit D10 and the like may be executed by a server.

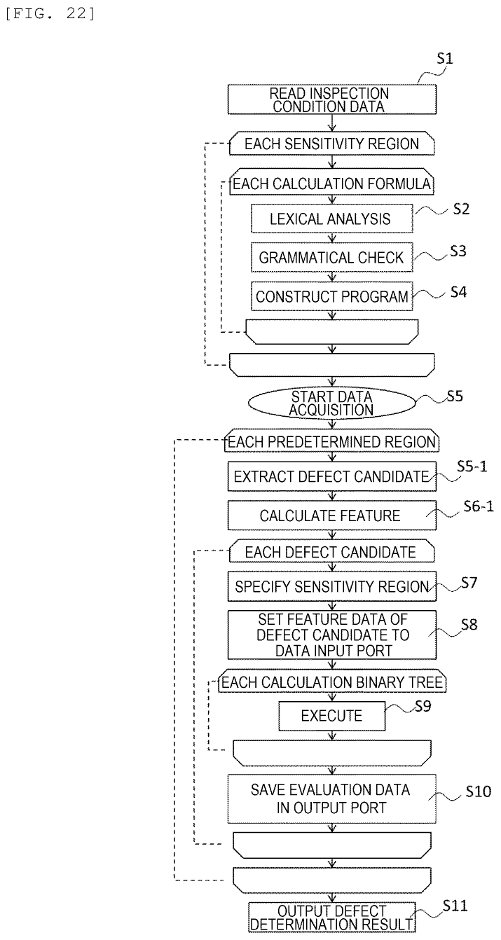

FIG. 17 is a schematic diagram showing an example of the frequency separation unit D10, the defect candidate detection unit D20, and the feature calculation unit D30 of the signal processing device D. Here, the total number of the sensors C1S to CnS and the sensors CIP to CnP is N. A detection signal photoelectrically converted by each sensor is converted into a digital signal by an A/D converter and is input to the frequency separation unit D10 of the signal processing device D.

### Frequency Separation Unit

The frequency separation unit D10 separates detection signals of the scattered light detection systems B1 to Bn into high-frequency components and low-frequency components. Specifically, the frequency separation unit D10 includes low-pass filters D11_1 to D11_N and difference calculation units D12_1 to D12_N. Based on detection signals α1 to αN input from the sensors, the low-pass filters D11_1 to D11_N generate low-frequency signals H1 to HN. The low-frequency signals H1 to HN are roughness scattered light intensities of the sample surface. The low-frequency signals H1 to HN are respectively subtracted from the detection signals α1 to αN by the difference calculation units D12_1 to D12_N to obtain high-frequency signals Sig1 to SigN.

### Defect Candidate Detection Unit

The defect candidate detection unit D20 detects defect candidates based on detection signals output from the scattered light detection systems B1 to Bn. For example, the defect candidate detection unit D20 calculates a normalized signal obtained by normalizing high-frequency components (the high-frequency signals Sig1 to SigN) of the detection signals α1 to αN of the scattered light detection systems B1 to Bn with shot noises estimated based on low-frequency components (the low-frequency signals H1 to HN), and sets a detection signal as a defect candidate when a magnitude of the normalized signal is larger than a threshold.

Specifically, the defect candidate detection unit D20 includes square calculation units D21_1 to D21_N, noise normalization units D22_1 to D22_N, an adder D23, and a binarization processing unit D24.

The square calculation units D21_1 to D21_N calculate squares of the high-frequency signals Sig1 to SigN respectively output from the difference calculation units D12_1 to D12_N. The noise normalization units D22_1 to D22_N divide calculation values of the square calculation units D21_1 to D21_N by the respective low-frequency signals H1 to HN output from the low-pass filters D11_1 to D11_N. The adder D23 calculates a sum of the calculation values of the noise normalization units D22_1 to D22_N. The binarization processing unit D24 compares an output value of the adder D23 with a preset threshold Th. An algorithm represented by Formula 1 can be executed by this data flow.

$${\sum }_{i} \frac{{Sig}_{i}^{2}}{{H}_{i}} > {Th}^{2} \qquad [ Formula 1 ]$$

In general, noises are shot noises caused by surface roughness scattered light, and are proportional to a square root of an amount of the roughness scattered light. Therefore, the high-frequency signals Sig1 to SigN are respectively squared by the square calculation units D21_1-D21_N, are normalized by the roughness scattered light by the noise normalization unit D22_1 to D22_N, and the sum of the normalized roughness scattered light is calculated by the adder D23. Accordingly, the square of a square norm of a defect candidate feature in a whitened feature data space is calculated as a normalized signal. A value of the normalized signal is compared with the threshold Th in the binarization processing unit D24, and when the normalized signal is larger than the threshold Th, the detection signals α1 to αN related to the normalized signal can be determined as defect candidates.

In the embodiment, in order to increase defect detection sensitivity, the threshold Th is set to be lower than a practical value (a value that is generally used in defect determination), and a defect candidate is detected under a condition that a large number of false alarms are output. The defect candidate obtained by the defect candidate detection unit D20 is subjected to final defect determination by evaluating a defect feature in subsequent processing. Since the number of defect candidates is large, it is important to speed up the feature evaluation unit D40 in a subsequent stage. Formula 1 is an example of a formula for extracting a defect candidate, and another alternative formula can be applied.

### Feature Calculation Unit

The feature calculation unit D30 calculates feature data (high-frequency signals Sig1 to SigN) of defect candidates based on the detection signals α1 to αN and inputs the feature data to a memory (input port D41 to be described later). In the embodiment, the feature calculation unit D30 calculates feature data (low-frequency signals H1 to HN) of the roughness scattered light from the sample surface based on the detection signals α1 to αN output from the scattered light detection systems B1 to Bn, and stores the feature data in a memory (input port D42 to be described later) together with the feature data of the defect candidates. An input port for storing the feature data of the roughness scattered light is an input port D43 in an example to be described later.

Specifically, the feature calculation unit D30 includes high-frequency signal output ports D31_1 to D31_N and low-frequency signal output ports D32_1 to D32_N. For a data set of the detection signals α1 to αN exceeding the threshold in the binarization processing unit D24, the feature calculation unit D30 outputs the high-frequency signals Sig1 to SigN from the high-frequency signal output ports D31_1 to D31_N and outputs the low-frequency signals H1 to HN from the low-frequency signal output ports D32_1 to D32_N. The high-frequency signals Sig1 to SigN output from the high-frequency signal output ports D31_1 to D31_N are a data set of feature data of defect candidates detected by sensors from certain coordinates on the sample. The low-frequency signals H1 to HN output from the low-frequency signal output ports D32_1 to D32_N are a data set of feature data of surface roughness of the sample detected by sensors from the same coordinates as those for the defect candidates. A set of feature data of the defect candidates and a set of feature data of surface roughness are stored in a memory (the input ports D41 and D42 to be described later) of the signal processing device D. Although not shown in FIG. 17, the feature data of the defect candidates also include coordinates on the sample where the defect candidates are detected.

### Feature Evaluation Unit

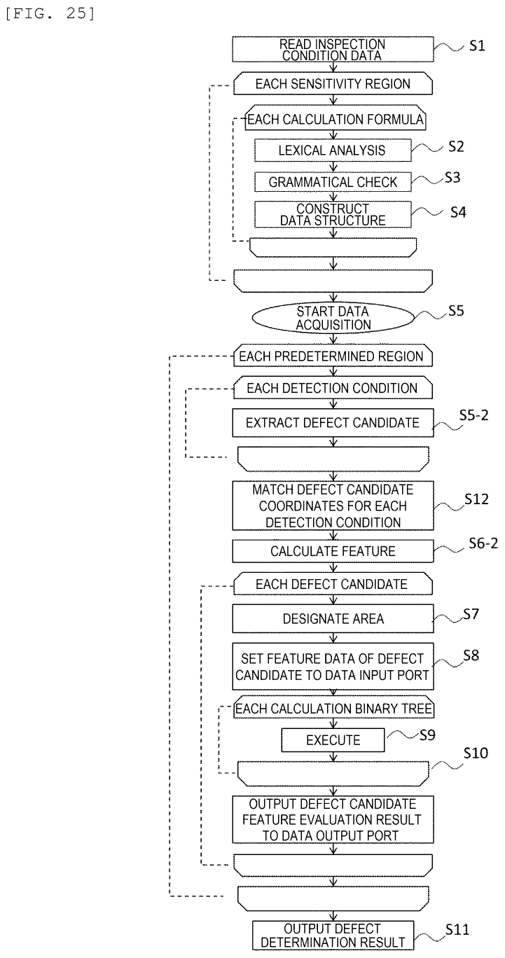

The feature evaluation unit D40 evaluates a defect candidate mainly based on a scattered light distribution in a far field. Although details will be described later, the feature evaluation unit D40 uses data of a data input unit (corresponding region of an input and output buffer of a memory) associated in a calculation data structure (for example, T-a shown in FIG. 20) configured by the defect feature evaluation instruction analysis unit D60 to calculate evaluation data of a defect candidate by sequentially executing, for each of calculation data structures (for example, T1a, T1b, . . . . T1n shown in FIG. 21) configuring a script data structure (for example, T1 shown in FIG. 21), processing of executing an instruction associated in the calculation data structure and storing an execution result in a data output unit (corresponding region of the input and output buffer of the memory). The “calculation data structure” and the “script data structure” described in the specification of the present application are not a data structure having general meaning as a data format, but are a simple program having a specific type of data structure (binary tree in this example) configured by the defect feature evaluation instruction analysis unit D60.

In particular, in the embodiment, the feature evaluation unit D40 sequentially executes the script data structure for the low-frequency signals H1 to HN in addition to the high-frequency signals Sig1 to SigN, and inputs evaluation data of a defect candidate reflecting data of the roughness scattered light to an output port. When the sample 1 is rotated and scanned, a difference in scanning speed occurs between an inner peripheral region and an outer peripheral region of the sample surface. Therefore, the script data structure executed by the feature evaluation unit D40 is configured by the defect feature evaluation instruction analysis unit D60 to be different for each region of the sample surface so as to correct a difference in an inspection condition caused by a scanning speed.

The feature evaluation unit D40 sequentially executes an instruction for each of the calculation data structures constituting the script data structure configured by the defect feature evaluation instruction analysis unit D60, calculates a similarity between a predetermined scattered light vector model and a feature data vector of a high-frequency component of a detection signal related to a defect candidate, and calculates evaluation data indicating that the defect candidate is a defect when the similarity exceeds a threshold. The threshold used here varies depending on a defect type.

FIG. 18 shows a basic concept of processing of the feature evaluation unit. FIG. 18 illustrates a plane coordinate system in which any two high-frequency signals Sigi and Sigj are plotted on a horizontal axis and a vertical axis for simplicity. In the figure, ex1 indicates a scattering direction vector of a specific defect type. In the inspection of a wafer, a type of an important defect to be detected is known in advance in many cases. For example, in the case of a purpose of dust generation control of a process device, a foreign substance on a sample surface is an important defect, and a scratch defect is a nuisance that does not require detection. On the other hand, in a wafer inspection after a polishing process, a scratch defect is an important defect. Assuming that ex1 is a scattering direction vector of an important defect, when an upper limit of an angle between a vector Sig to be evaluated and the vector ex1 is Th_θ, a region ex2 in which the upper limit is less than Th_θ in the coordinate system shown in FIG. 18 corresponds to a feature of the important defect. The angle formed by the vectors Sig and ex1 is the similarity described above, and Th_θ is a threshold. The threshold Th_θ varies depending on a defect type. The region ex2 is expressed by Formula 2.

$$Sig \cdot ex 1 > ‖ Sig ‖ ‖ ex 1 ‖ cos Th\_θ \qquad [ Formula 2 ]$$

In general, the scattering direction vector ex1 of the important defect is determined by actually performing an inspection in an inspection process, and may be changed as a result of trial and error including a signal type (such as Sigi described above) and a threshold (such as Th_θ described above) serving as parameters. In the embodiment, in order to enable such a change, a defect determination condition can be described in a script format according to a feature of a defect and input to the signal processing device D. For example, a script input can be performed by inputting, into the signal processing device D, a defect determination condition file created by operating an input device in the control device E10. A defect condition determination file created by another computer can also be input to the signal processing device D via a network or a storage medium.

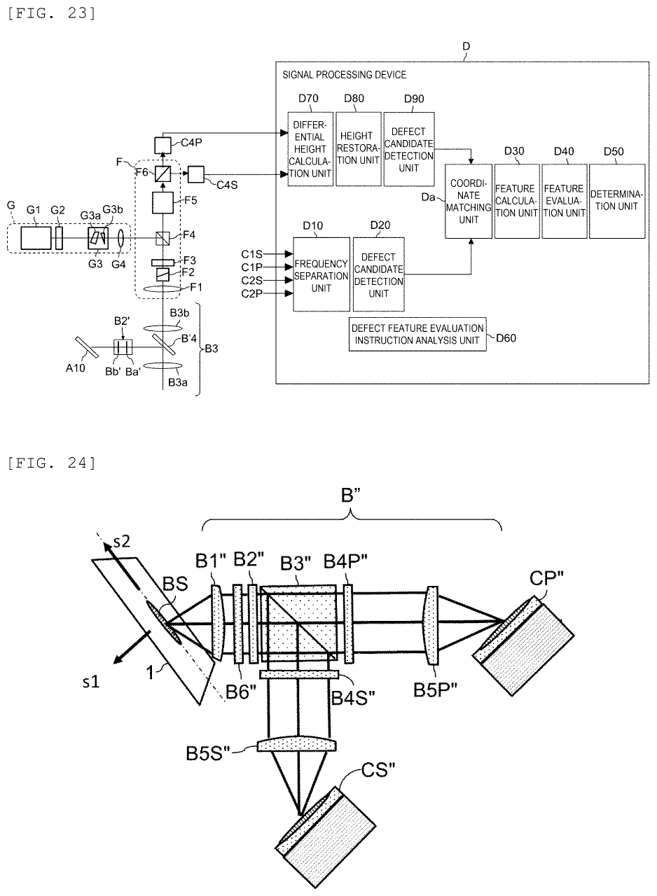

FIG. 19 shows an example of input and output ports and scripts constituting the feature evaluation unit D40. The feature evaluation unit D40 includes the input ports D41 and D42, the output port D43, a parameter port D44, and a threshold port D45. These ports are input and output ports of an input and output buffer of a memory area. The input port D41 is a port for inputting the high-frequency signals Sig1 to SigN as feature data vectors of defect candidates. The input port D42 is a port for inputting the low-frequency signals H1 to HN as feature data vectors of the surface roughness. The output port D43 is a port for outputting evaluation data (flags E0 to E3 in FIG. 19) of a defect candidate. The parameter port D44 is a port for outputting a scattered light vector (for example, ex1 in Formula 2) of each defect model as a parameter. The threshold port D45 is a port for outputting a threshold (for example, Th_θ in Formula 2) used for a defect determination condition.

sr1 and sr2 are examples of scripts describing a defect determination condition executed by the feature evaluation unit D40. In the scripts sr1 and sr2, an instruction, an input port, an output port, and the like related to evaluation of a defect feature are described in a set of formulas of a typical intermediate notation. “+”, “−”, “*”, and “/” used in description of the scripts sr1 and sr2 indicate addition, subtraction, multiplication, and division, and in particular, “+” and “*” also represent a logical sum and a logical product. “\hat{ }” indicates power, and “=” indicates substitution. Combinations of alphabets and numbers such as “S_NORM” and “P0_NORM” indicate internal parameters to be applied. “$” indicates a reference. For example, $SigL indicates that an L-th port of the input port D41 is referred to. “>” indicates a comparison operator, “!” indicates negative in a calculation result.

Intermediate data to be calculated is described in the script sr1. SNR included in the script sr1 describes a left side of Formula 1. S_NORM is an L2 norm of a vector Sig to be evaluated, and P0_NORM, P1 NORM, and P2 NORM are L2 norms for a model of scattered light of a specific defect type. The intermediate data calculated by the script sr1 is not input or output from the feature evaluation unit D40, and is subjected to processing such as calculation and storage inside the feature evaluation unit D40.

D0 is used to obtain the cosine of an angle formed by the vector Sig of the scattered light to be evaluated and a scattering direction vector P0 of a model of a specific defect type. Similarly, D1 and D2 are used to obtain the cosine of angles formed by the vector Sig and scattering direction vectors P1 and P2 of models of the other specific defect types.

The script sr2 is a script for calculating evaluation data (evaluation result). E1, E2, E3, and E0 are flags representing evaluation data calculated by the script sr2, and are stored in the corresponding data output unit (designated region and address in the input and output buffer) in the calculation data structure and are output from the output port D43 to the determination unit D50. For example, the flag E1 is set such for a data set in which a scattered light distribution is closest to a model defect represented by feature data P01 to P0N read from the parameter port D44 (P0 port) (D>D1, D0>D2) and the degree of proximity represented by the cosine is larger than a threshold Th2 (D0 >Th2), among data sets output from the feature calculation unit D30. Similarly, the flag E2 is set for a data set in which a scattered light distribution is closest to defects represented by feature data P11 to PIN read from the parameter port D44 (P1 port) and the degree of proximity is larger than the threshold Th2, among the data sets output from the feature calculation unit D30. Similarly, the flag E3 is set for a data set in which a scattered light distribution is closest to defects represented by feature data P21 to P2N read from the parameter port D44 (P2 port) and the degree of proximity is larger than the threshold Th2, among the data sets output from the feature calculation unit D30. A defect type is specified from an added flag. In the embodiment, for example, a feature data vector of a defect model of a nuisance is stored in the P0 port, and a feature data vector of a defect model of an important defect is stored in the P1 port and the P2 port.

The flag E0 is set for a data set determined to be similar to a scattered light distribution of a defect of the P1 port or the P2 port and a data set whose SNR exceeds a threshold Th0. On the other hand, in a data set determined to be similar to a scattered light distribution of a defect of the P0 port, the flag E0 is not set unless the SNR exceeds Th1. A data set in which the flag E0 is not set is determined to be noises in the embodiment, and is excluded from defect candidate data in subsequent processing. The thresholds Th0 and Th1 included in the script sr2 are both larger than the threshold Th of Formula 1, and Th0<Th1. That is, the threshold used in Formula 1 is applied to a data set determined to be approximate to an important defect of the P1 port or the P2 port, and a highly sensitive inspection is achieved. The threshold Th1 input to the threshold port D45 is applied to a data set determined to be approximate to the scattered light vector P0 of a nuisance, and inspection sensitivity is lowered.

In order to improve defect detection sensitivity, it is necessary to first extract a large number of defect candidates by threshold processing of D24 and analyze detailed defect scattered light shown in the scripts sr1 and sr2. However, it is difficult to interpret codes of the intermediate notation as shown in the scripts sr1 and sr2 and execute a large amount of sequential processing due to a large calculation load of the signal processing device D. Therefore, in the embodiment, in order to enable the sequential processing of the feature evaluation unit D40, prior to the processing of the feature evaluation unit D40, a script data structure in which the feature evaluation unit D40 can uniquely execute processing when a defect determination condition file is read into the signal processing device D is configured by the defect feature evaluation instruction analysis unit D60.

### Defect Feature Evaluation Instruction Analysis Unit

The defect feature evaluation instruction analysis unit D60 assumes predetermined regions of the input and output buffer, which are specific memory areas, as the input ports D41 and D42, the output port D43, the parameter port D44, and the threshold port D45, inputs defect determination scripts (for example, sr1 and sr2 in FIG. 19) describing data processing related to feature data evaluation, and analyzes the defect determination scripts. Then, the defect feature evaluation instruction analysis unit D60 configures a calculation data structure (for example, T-a in FIG. 20) having a data structure in which a data input unit (a designated region in the input and output buffer, for example, an address), an instruction using data input to the data input unit, and a data output unit (a designated region in the input and output buffer, for example, an address) that stores execution data (execution result) of the instruction are associated with one another. The defect feature evaluation instruction analysis unit D60 configures the calculation data structure for each statement of the script (for example, each row of sr1 and sr2 in FIG. 19), and configures a script data structure (for example, T1 in FIG. 21) including a plurality of the calculation data structures (for example, T1a, T1b, . . . . T1n in FIG. 21). In particular, in the embodiment, the feature data (low-frequency signals H1 to HN) of the roughness scattered light is input to the input port D42. Therefore, the defect feature evaluation instruction analysis unit D60 can handle not only the feature data of the defect candidates (high-frequency signals Sig1 to SigN) but also a defect determination script describing data processing related to evaluation of the feature data of the roughness scattered light (low-frequency signals H1 to HN), and can configure the calculation data structures and the script data structure based on the defect determination script related to the evaluation of feature data of the defect candidates and feature data of the roughness scattered light.

FIG. 20 is a schematic diagram showing a calculation data structure of a calculation binary tree structure corresponding to the SNR included in each of the defect determination scripts sr1 and sr2. In the binary tree, an operator, a value, and a variable are assigned to each node. The node is connected to one parent node and at most two child nodes. In each node, a set calculation is executed for at most two child nodes, and a calculation result is returned to the parent node. In the embodiment, a dedicated type of node is used for each operator. For example, a calculation corresponding to a type of each node in a one-to-one relationship is assigned such that a “+node” is assigned to “+”, a “* node” is assigned to “*”, and accordingly, interpretation of calculation contents and case classification becomes unnecessary at the time of calculation execution, and processing can be performed at high speed. For example, when focusing on a subtree t in FIG. 20, a node in which Sig0 is set as a variable corresponds to a 0-th port of the input port D41, and when feature data is input to the 0-th port, the feature data is sequentially squared according to an algorithm represented in the subtree t. In this manner, each time data set of feature data is stored in the input ports D41 and D42, the data set is referred to in the calculation data structure in FIG. 20, and a calculation of each node is uniquely executed. In this manner, for example, intermediate data calculated in each of the calculation data structures T1a to Tn in FIG. 21, and evaluation data serving as an execution result of the script data structure T1 are stored in the data output unit of the input and output buffer. Such processing is sequentially executed, and evaluation data (flags E0 to E3) of each defect candidate is stored in the corresponding data output unit and is output from the output port D43 to the determination unit D50.

FIG. 21 is a view schematically showing the entire script data structure generated by the defect feature evaluation instruction analysis unit D60 based on a defect determination condition file. When a sample is rotated and scanned in a spiral trajectory, a scanning speed generally tends to be faster toward the outer periphery and slower toward the center. Therefore, the script data structure can be set for each region of the sample 1. For example, the script data structures T1, T2, and T3 including a plurality of calculation data structures Tia to Tin are generated in each of regions r1, r2, and r3 obtained by dividing the sample 1 at radial positions on the sample surface. In this example, the script data structure T1 including the calculation data structures T1a to T1n is configured based on sr1 and sr2 for defect candidates in the region r1. Similarly, the script data structure T2 including the calculation data structures T2a to T2n is configured based on sr1 and sr2 for defect candidates in the region r2. The script data structure T3 including the calculation data structures T3a to T3n i configured based on sr1 and sr2 for defect candidates in the region r3. The generation of the script data structures T1, T2, and T3 is executed by the defect feature evaluation instruction analysis unit D60.

When the sample 1 is inspected, the feature evaluation unit D40 determines in which region a defect candidate is detected based on coordinate data included in feature data of the defect candidate, and executes a corresponding one of the script data structures T1, T2, and T3. Specifically, the calculation data structures T1a to T1n belonging to the script data structure T1 are executed for a defect candidate detected in the region r1. The calculation data structures T2a to T2n belonging to the script data structure T2 are executed for a defect candidate detected in the region r2. The calculation data structures T3a to T3n belonging to the script data structure T3 are executed for a defect candidate detected in the region r3. As an execution result of each script data structure, evaluation data is stored in the output port D43 for each defect candidate.

Although an evaluation method using both of the defect feature data vectors (high-frequency signals Sig1 to SigN) and the surface roughness feature vectors (low-frequency signals H1 to HN) has been described in the embodiment, a defect candidate may be evaluated using the defect feature data vectors only.

### Determination Unit

The determination unit D50 determines whether a defect candidate is a defect based on evaluation data output from the output port D43, that is, the flags E0 to E3. In the output port D43, one of the flags E1 to E3 and two flags of the flag E0 can be set. A defect candidate in which the flag E0 is set indicates that the defect candidate exceeds a relatively large threshold Th1 or approximates to any defect model stored in the parameter port D44 (P0 port to P2 port). Therefore, the determination unit D50 keeps the defect candidate in which the flag E0 is set, and excludes a defect candidate in which the flag E0 is not set. Among the parameter ports D44, a defect candidate that is approximate to a nuisance defect model stored in the P0 port may be excluded or classified into a nuisance defect class.

### Inspection Flow of Signal Processing Device

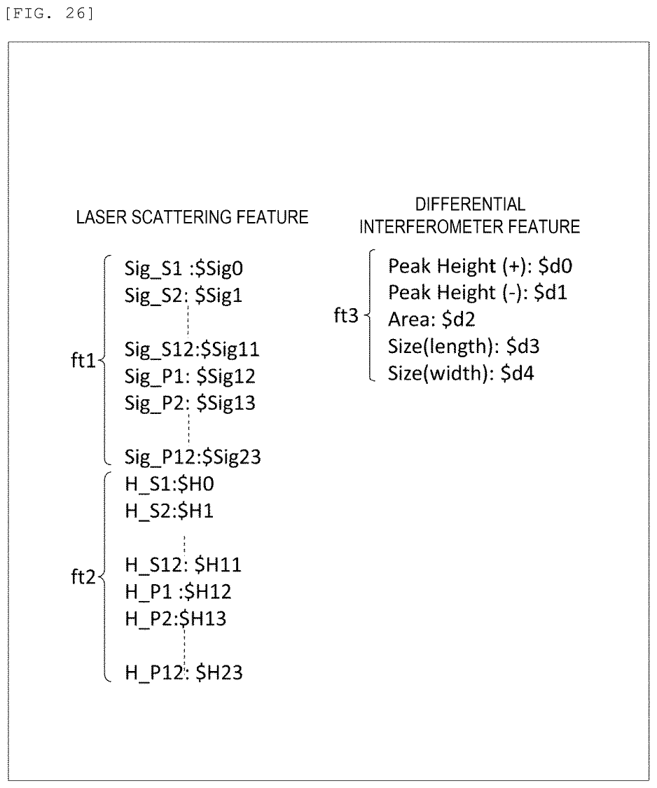

FIG. 22 shows an inspection flow of the signal processing device. First, the signal processing device D reads defect determination condition data (S1). Scripts indicated by the scripts sr1 and sr2 are described in the defect determination condition data. Next, the signal processing device D performs a lexical analysis (S2) and a grammatical analysis (S3) on each calculation formula of a script corresponding to a sensitivity region in the loop of sensitivity regions (regions r1 to r3) shown in FIG. 21. Although not shown, when there is an error in grammar, the signal processing device D interrupts an inspection and requests input of normal defect determination condition data.

Next, the signal processing device D configures a script data structure including a calculation binary tree synonymous with the scripts sr1 and sr2 (S4). When the configuration of the script data structure is completed for all of the sensitivity regions, the signal processing device D starts acquiring a detection signal from the sample 1 (S5). In this example, when data acquisition (for example, scanning for X rounds set in advance) in a predetermined region is completed, the signal processing device D processes the acquired detection signal in parallel with scanning to extract a defect candidate (S5-1), and calculates feature data of the defect candidate (S6-1). The signal processing device D specifies a sensitivity region in which a defect candidate is detected based on coordinate data included in the feature data of the defect candidate (S7), and sets the feature data in the input ports D41 and D42 to be accessed by the feature evaluation unit D40 (S8). Then, the signal processing device D executes the script data structure corresponding to the specified sensitivity region (S9). As a result, evaluation data of the feature data is stored in the output port D43. The signal processing device D saves the evaluation data in another memory area, and finally outputs a defect determination result to the monitor E30 (S11).

### Effects

As described above, according to the embodiment, the signal processing device D reads a script describing detailed data processing contents, for example, detailed algorithms such as removal of a nuisance, extraction of a defect candidate, and classification of a defect candidate are described at the time of setting a defect determination condition, and configures the script data structures T1, T2, and T3 having a data structure that uniquely executes processing described in the script. Accordingly, the defect determination condition can be flexibly adjusted, and an important defect can be detected at high speed and with high sensitivity.

In addition, since data of the roughness scattered light can be reflected in evaluation for a defect candidate, a defect can be evaluated in more details.

### Second Embodiment

Although only scattered light with respect to oblique illumination or illumination from above is used in the first embodiment, it is also possible to add a result of a different scattered light detection system thereto. In the second embodiment, an example using a differential interferometer will be described.

FIG. 23 is a diagram schematically showing a scattered light illumination system, a scattered light detection system, and a signal processing system of a differential interferometer provided in a defect inspecting device according to the second embodiment of the invention. FIG. 23 mainly shows configurations different from those of the first embodiment, and configurations common to those of the first embodiment are omitted as appropriate. In addition, in the drawing, the same elements as those in the previous drawings are denoted by the same reference numerals as those in the previous drawings, and description thereof will be omitted.

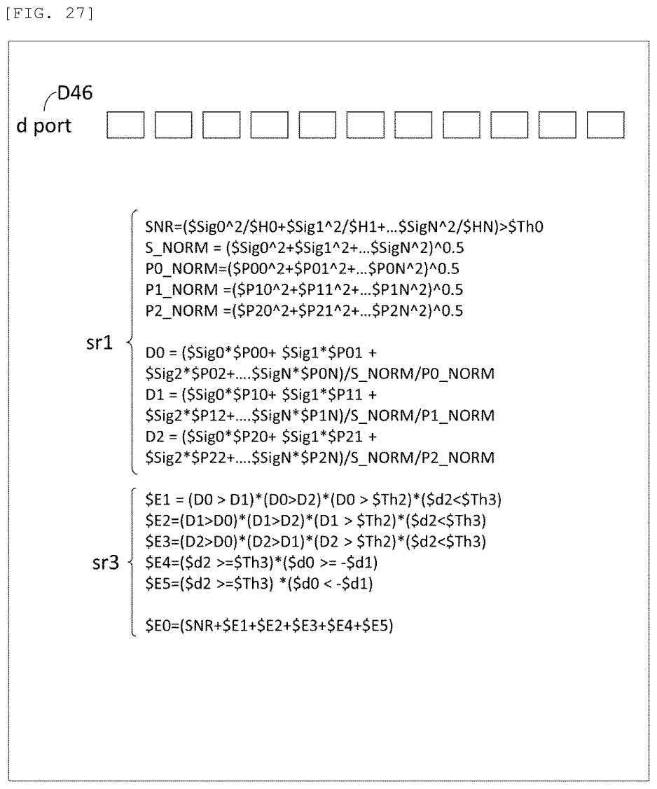

To summarize, first, the defect inspecting device according to the embodiment includes a differential interference illumination system G and a differential interference detection system F in addition to the hardware described in the first embodiment. The differential interference illumination system G forms an illumination spot on a sample surface with light having a different wavelength from the light emitted from the scattered light illumination system A. The differential interference detection system F detects light from the illumination spot formed by the differential interference illumination system G. The scattered light detection systems B1 to Bn are provided with an optical filter (in this example, a bandpass filter B6″ shown in FIG. 24) that filters a wavelength of the differential interference illumination system.

Next, as software, the signal processing device D in the embodiment includes a defect candidate detection unit D20 that detects a first defect candidate group based on detection signals of the scattered light detection systems B1 to Bn, and a defect candidate detection unit D90 that detects a second defect candidate group based on a detection signal of the differential interference detection system I F. In addition, the signal processing device D includes a coordinate matching unit Da that compares defect coordinates of the first defect candidate group with defect coordinates of the second defect candidate group and treats defect candidates having a deviation amount equal to or less than a set distance as the same defect candidate. Based on coordinate comparison data of the coordinate matching unit Da, the feature calculation unit D30 in the embodiment calculates integrated feature data obtained by integrating feature data (first feature data) related to the detection signals of the scattered light detection systems B1 to Bn and feature data (second feature data) related to the detection signal of the differential interference detection system F, and inputs the integrated feature data to an input port of a memory as feature data of a defect candidate. The feature evaluation unit D40 sequentially executes the script data structure configured by the defect feature evaluation instruction analysis unit D60 for the integrated feature data stored in the data input unit of the input and output buffer via the input port, stores evaluation data of the defect candidate in a data output of the input and output buffer, and outputs the data from the output port D43.

Details will be described below.

### Differential Interference Illumination System

In the embodiment, the differential interference detection system F is provided instead of the sensors C3P and C3S disposed directly above a wafer. The differential interference detection system F detects laser light radiated onto the sample 1 from the differential interference illumination system G provided in the defect inspecting device separately from the scattered light illumination system A. Although not shown, elements other than the sensors C3P and C3S in the hardware described in the first embodiment are also provided in the defect inspecting device in the embodiment.

The differential interference illumination system G includes a laser light source G1, an attenuator G2, a beam expander G3, and an illumination lens G4. The attenuator G2 has substantially the same configuration as the attenuator A2. As a wavelength of the laser light source G1, a wavelength different from that of the laser light source A1 is selected. The beam expander G3 includes an anamorphic prism pair G3a and G3b, and an aspect of illumination is changed by the anamorphic prism pair G3a and G3b so that linear illumination is formed on the sample surface. The illumination lens G4 forms a reduced image of a beam in combination with an objective lens F1, and forms an image of the illumination spot formed here on the sample surface by a relay lens system. Similar to the first embodiment, the relay lens system is formed by a combination of the condenser lens B3a and the imaging lens B3b. However, a dichroic mirror B′4 is mounted instead of the reflection mirror B1′ in the embodiment. The dichroic mirror B′4 reflects light having the wavelength of the laser light source A1 and transmits light having the wavelength of the laser light source G1.

### Differential Interference Detection System

The differential interference detection system F includes the objective lens F1, a Nomarski prism F2, a ¼ wavelength plate F3, a half beam splitter F4, an imaging lens F5, and a polarization beam splitter F6. Light emitted from the polarization beam splitter F6 is imaged by line scan sensors C4P and C4S. The line scan sensors C4P and C4S detect light in polarization directions orthogonal to one another.

Light emitted from the illumination lens G4 is reflected by the half beam splitter F4 by half of an illumination light amount, and is incident on the ¼ wavelength plate F3. Although not shown, the remaining half of the light transmitted through the half beam splitter F4 is extinguished by a diffuser. Light emitted from the attenuator G2 is linearly polarized light, the ¼ wavelength plate F3 is disposed such that a fast axis is shifted by 45° relative to a polarization direction of the linearly polarized light, and light emitted from the ¼ wavelength plate F3 is circularly polarized light. The light emitted from the ¼ wavelength plate F3 and passing through the Nomarski prism F2 is separated into two light beams having polarization directions orthogonal each other. A position of the Nomarski prism F2 is adjusted such that a cross point of the two light beams coincides with a pupil position of the objective lens F1. As a result, the light emitted from the Nomarski prism F2 and passing through the objective lens F1 is imaged as two linear illumination spots shifted by a shear amount on the sample surface via the imaging lens B3b and the condenser lens B3a. Light reflected from the two illumination spots on the sample surface returns to the Nomarski prism F2 via the condenser lens B3a, the imaging lens B3b, and the objective lens F1. One beam of light that passed through the Nomarski prism F2 returns to the Nomarski prism F2, and is imaged on the line scan sensors C4P and C4S via the imaging lens 5 and the polarization beam splitter F6.

At this time, in a case where there is a step (height difference) between the two illumination spots formed on the sample surface, the light that is circularly polarized light at a stage of being incident on the Nomarski prism F2 from the ¼ wavelength plate F3 changes to elliptically polarized light when the light is incident on the ¼ wavelength plate F3 from the Nomarski prism F2. As a result, a light intensity at which the imaging lens F5 forms an image on light receiving surfaces of the line scan sensors C4P and C4S changes according to the step between the two illumination spots formed on the sample surface.

### Signal Processing Device

The signal processing device D in the embodiment includes a differential height calculation unit D70, a height restoration unit D80, the defect candidate detection unit D90, the coordinate matching unit Da, and the feature calculation unit D30 in addition to the frequency separation unit D10, the defect candidate detection unit D20, the feature calculation unit D30, the feature evaluation unit D40, the determination unit D50, and the defect feature evaluation instruction analysis unit D60. Similar to the frequency separation unit D10, the defect candidate detection unit D20, the feature calculation unit D30, the feature evaluation unit D40, the determination unit D50, and the defect feature evaluation instruction analysis unit D60, the differential height calculation unit D70, the height restoration unit D80, the defect candidate detection unit D90, the coordinate matching unit Da, and the feature calculation unit D30 may be virtually implemented by software or may be implemented by hardware such as an electronic circuit.

The differential height calculation unit D70 processes image data acquired by the differential interference detection system F, and calculates a differential height Δh, that is, a difference between the two illumination spots formed on the sample 1 by shifting by the shear amount, based on outputs of the line scan sensors C4P and C4S. A luminance signal input from the line scan sensor C4P is denoted by IP, and a luminance signal input from the line scan sensor C4S is denoted by IS. At this time, the differential height Δh is expressed by the following Formula, in which λ is a wavelength of light emitted from the laser light source G1.

$$Δ h = \frac{λ}{4} sin ( \frac{IP - IS}{IP + IS} ) \qquad [ Formula 3 ]$$

The differential height calculation unit D70 calculates a height change between the two points shifted by the shear amount based on Formula 3. The differential height Δh can be obtained for each corresponding pixel of the line scan sensors C4P and C4S.

The height restoration unit D80 restores (calculates) a height of the sample surface by deconvoluting the differential height Δh calculated by the differential height calculation unit D70. The defect candidate detection unit D90 compares the restored height of the sample surface with a reference value, and detects, as a defect candidate, a region in which the height is different from the reference value beyond a set value or a region in which the differential height Δh exceeds a set value.

Processing executed by the frequency separation unit D10 and the defect candidate detection unit D20 are the same as those in the first embodiment. Since it is difficult to completely match positions of the illumination spots of the scattered light illumination system A and the differential interference illumination system G, the coordinate matching unit Da performs matching between defect candidates output by the defect candidate detection units D20 and D90. For example, coordinates of a defect candidate detected by the scattered light detection systems B1 to Bn and coordinates of a defect candidate detected by the differential interference detection system F are compared with each other, and defect candidates whose coordinates are shifted from each other by a predetermined distance or less are matched as defect candidates detected at the same coordinates. Defect candidates matched by the coordinate matching unit Da indicate a defect detected by both the scattered light detection systems B1 to Bn and the differential interference detection system F, and defect determination is performed based on feature data obtained by both the scattered light detection systems B1 to Bn and the differential interference detection system F. A defect candidate that is detected by the defect candidate detection unit D90 but is not a defect candidate whose coordinates are shifted from a defect candidate detected by the defect candidate detection unit D20 within the predetermined distance is treated as a defect candidate detected only by the differential interference detection system F. On the other hand, a defect candidate that is detected by the defect candidate detection unit D20 but is not a defect candidate whose coordinates are shifted from a defect candidate detected by the defect candidate detection unit D90 within the predetermined distance is treated as a defect candidate detected only by the scattered light detection systems B1 to Bn.

In the embodiment, the feature calculation unit D30 collects data output from the defect candidate detection units D20 and D90 for each defect candidate. A data set of features collected by the feature calculation unit D30 is evaluated by the feature evaluation unit D40 in the same manner as that in the first embodiment, and defect determination or classification is performed by the determination unit D50. The feature evaluation unit D40 uses a script applied to the embodiment.

### Oblique Imaging Detection System

Although a point sensor is used as a sensor for detecting light from the scattered light detection systems B1 to Bn in the first embodiment, a line sensor is applied in the embodiment. When an illumination spot on the sample surface is obliquely detected, a working distance between the sample surface and the objective lens varies depending on a distance from an optical axis of the objective lens. Therefore, when a light receiving surface of a sensor is orthogonal to an optical axis of the detection system, defocus occurs. Therefore, the light receiving surface of the sensor is tilted relative to the optical axis so that the light receiving surface of the sensor is conjugate with the sample surface. This point will be described with reference to FIG. 24.

An oblique imaging detection system B″ includes an objective lens B1″, the bandpass filter B6″, a ½ wavelength plate B2″, a polarization beam splitter B3″, ½ wavelength plates B4P″ and B4S″, and imaging lenses B5P″ and B5S″.

The ½ wavelength plate B2″ can be rotated by a rotation mechanism (not shown), and can rotate a polarization direction of light detected by the objective lens B1″ to a desired direction. The polarization beam splitter B3″ splits the detected light into two optical paths of P-polarized light and S-polarized light. The ½ wavelength plate B4P″, the imaging lens B5P″, and the line sensor CP″ are arranged on an optical path of the P-polarized light. Similarly, the ½ wavelength plate B4S″, the imaging lens B5S″, and the line sensor CS″ are arranged on an optical path of S-polarized light. The ½ wavelength plates B4P″ and B4S″ are each set on a rotation stage (not shown), and rotate the polarization direction such that detection efficiency of the line sensors CP″ and CS″ is optimized.

The line sensors CP″ and CS″ are tilted relative to the optical axis of the oblique imaging detection system B″ so as to be conjugate with the illumination spot BS on the sample surface. The bandpass filter B6″ transmits light having an illumination wavelength of the laser light source A1 and does not transmit light having an illumination wavelength of the laser light source G1, so that scattered light detection is not affected by the light from the laser light source G1.

### Inspection Flow of Signal Processing Device

FIG. 25 shows an inspection flow of the signal processing device. In the flow shown in FIG. 25, the same processing as that in FIG. 22 are denoted by the same step number as that in FIG. 22 and description thereof is omitted. Here, processing different from that in FIG. 22 will be described. Steps S1 to S5 are the same as those in the flow shown in FIG. 22. In the embodiment, the signal processing device D extracts a defect candidate for each inspection method, that is, for each scattered light inspection and each differential interference inspection (S5-2), and performs coordinate matching between detection signals obtained by the two inspection methods to identify a defect candidate detected by only one of the inspection methods and a defect candidate detected by both of the inspection methods (S12). Then, the signal processing device D calculates a defect feature obtained by integrating features obtained by both of the inspection methods based on a result of the coordinate matching, and stores the defect feature in the input port (S6-2). Subsequent steps S7 to S11 are the same as those in FIG. 22.

### Feature Data

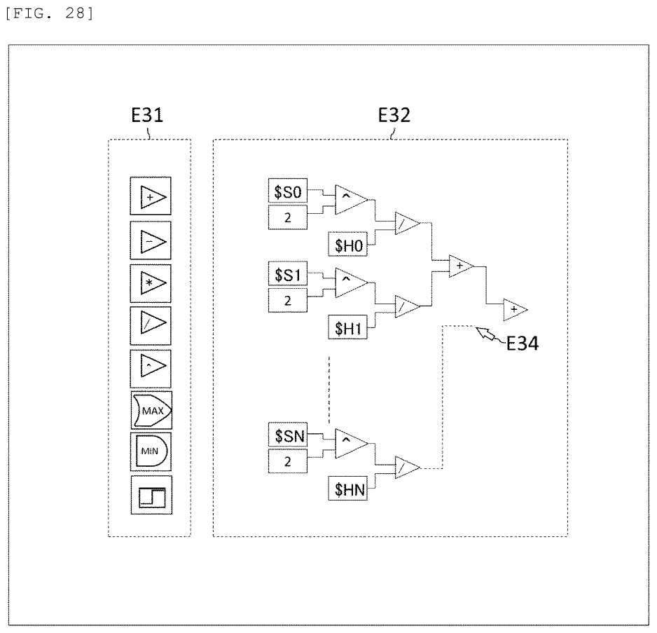

FIG. 26 shows defect features detected by laser scattering and the differential interferometer. ft1 is a high-frequency component of a laser scattering intensity output from the high-frequency signal output ports D31_1 to D31_N, and ft2 is a low-frequency component of a laser scattering intensity output from the low-frequency signal output ports D32_1 to D32_N, which are calculated by the defect candidate detection unit D20. ft3 is feature data calculated from an image acquired by the differential interferometer, and is calculated by the defect candidate detection unit D90. Further, based on a height restoration image, a region higher than a predetermined reference plane by a set height or more and a region lower than the predetermined reference plane by a set height or more are calculated as a defect candidate region, a maximum height in the defect candidate region is calculated as Peak_Height (+), a minimum height is calculated as Peak_Height (−), the area of the defect candidate region is calculated as Area, a length of the defect candidate region is calculated as Size (length), and a width of the defect candidate region is calculated as Size (width). In the embodiment, data of these pieces of feature data is additionally calculated by the feature calculation unit D30.

FIG. 27 shows an example of an input and output port and scripts constituting the feature evaluation unit D40 in the embodiment. In the embodiment, in addition to the input ports shown in FIG. 19, a d port D46 that accesses a feature of ft3 is set as a port of the feature evaluation unit D40. ft1 is set to the input port D41 (FIG. 19), ft2 is set to the input port D42, and ft3 is set to the d port D46 (FIG. 27), so that ft1, ft2, and ft3 can be accessed from the feature evaluation unit D40. For a defect candidate detected only by laser scattering, all of Peak_Height (+), Peak_Height (−), Area, Size (length), and Size (Width) of differential interference feature data are set to 0. Similarly, for a defect candidates detected only by the differential interferometer, all pieces of feature data of ft1 are set to 0. Since ft2 is typically feature data of the low-frequency signals H1 to HN, ft2 can also be acquired from coordinates that are not defect candidates on the sample surface.

The script sr1 shown in FIG. 27 is the same as that shown in FIG. 19. The script sr3 corresponds to a script obtained by adding the feature data of ft3 to the script sr2. An execution result of these scripts is output to the output port D43.

### GUI

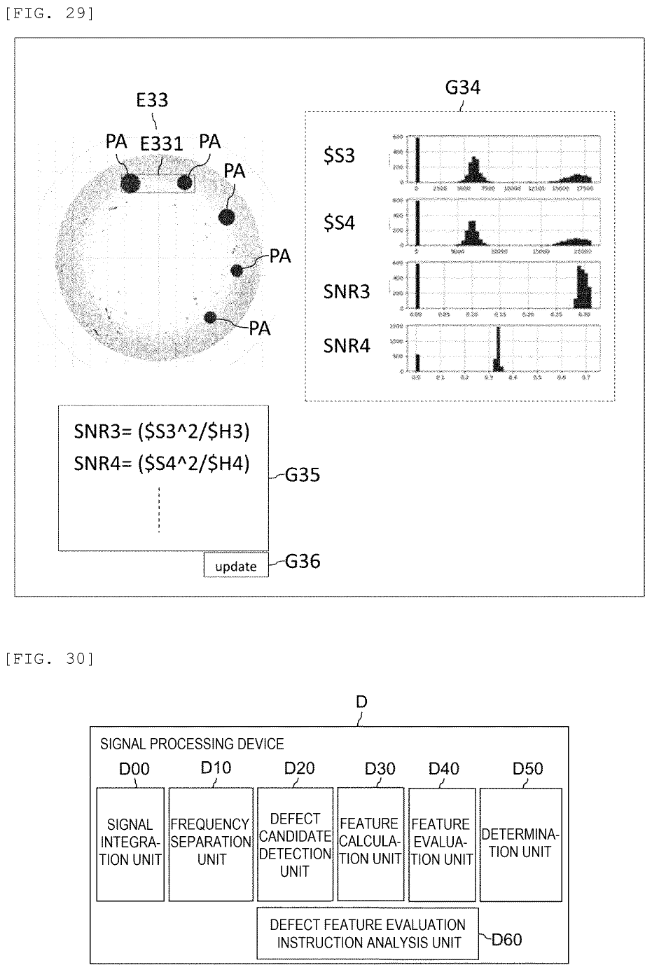

FIG. 28 shows a screen for supporting creation of a script to be displayed on the monitor E30. A selectable operator group E31 is displayed on this screen. In the example shown in FIG. 28, operators and links such as addition, subtraction, multiplication, division, . . . are vertically arranged in a region on a left side of the screen as the operator group E31. A region E32 where visual programming can be performed is displayed on a right side of the screen. A pointer E34 is operated by an input device, a plurality of freely selected operators are dragged and arranged from the operator group E31 to the region E32, the operators and input values are appropriately connected by a link, and an input and output relationship of data is set on the GUI. The logic set in the region E32 is equivalent to the binary tree shown in FIG. 20, and a data structure can be set in the region E32. It is also possible to generate a formula of an intermediate notation based on the binary tree.

FIG. 29 shows a confirmation screen of scripts and parameters. A data set of defect feature data acquired during an inspection is accumulated in the secondary storage device DB, and when a defect determination condition is set, the data set is displayed on the monitor E30, and the scripts and the parameters can be adjusted (fine tuning). On the screen shown in FIG. 29, a wafer map E33 which is an inspection image of the sample 1 is displayed in a left region. The wafer map E33 displays defects detected from the sample 1. FIG. 29 shows the wafer map E33 of a standard sample in which standard particles are sprayed in predetermined regions PA by an atomizer. The detected defects (dark shadow portions mainly concentrated on the regions PA) correspond to any one flag of the output port D43.

A script description field G35 is displayed on a lower side of the screen, and by pressing an update button G36 after a script is described or appropriately corrected in the description field G35, the script described in the description field G35 is applied to a data set of defect feature data stored in the secondary storage device DB for the sample 1 related to the wafer map E33, and an execution result of the script is reflected in the wafer map E33.

A histogram G34 is displayed on a right side of the screen. The histogram G34 is displayed for data of a region E331 set by dragging with a pointer in the wafer map E33. In the case of a standard sample, a defect candidate detected in the region PA is a true defect, and a defect candidate detected in a region other than the small region PA is substantially a false alarm. Using this point, the scripts and parameters in the description field G35 and the like are adjusted so that defects are detected only in the regions PA as much as possible.

According to the embodiment, in addition to effects the same as those of the first embodiment, data obtained by the differential interferometer is reflected in the defect inspection, and a defect can be inspected with higher accuracy and higher sensitivity. Further, the script data structure executed by the feature evaluation unit D40 can be more intuitively and easily designed by the GUI shown in FIG. 28.

### Third Embodiment

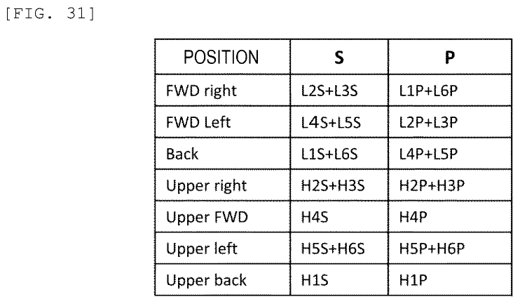

FIG. 30 is a diagram showing main parts of a third embodiment. The third embodiment is a modification of the first embodiment. The signal processing device D according to the embodiment includes a signal integration unit D00 in addition to the processing units provided in the signal processing device D according to the first embodiment. Similar to the frequency separation unit D10, the defect candidate detection unit D20, the feature calculation unit D30, the feature evaluation unit D40, the determination unit D50, and the defect feature evaluation instruction analysis unit D60, the signal integration unit D00 may be virtually implemented by software or may be implemented by hardware such as an electronic circuit.

The signal integration unit D00 is provided at a first stage of the signal processing device D, and executes processing at the beginning of a signal processing flow related to defect determination prior to the frequency separation unit D10. A signal processed by the signal integration unit D00 is processed by the frequency separation unit D10 and subsequent units.

As shown in FIG. 7, when an opening in the far field is divided into small regions, the scattered light distribution can be analyzed in details, but an amount of scattered light that can be detected by one opening decreases, and the SNR decreases. In addition, since there are many pieces of scattered light data acquired from the same coordinates on the sample, a calculation load of the signal processing device D increases, which may lead to an increase in device costs.

Therefore, as shown in a table in FIG. 31, signals of the sensors are integrated to perform subsequent processing. In the example shown in FIG. 31, for example, regarding light scattered to a front right side, an integrated signal obtained by integrating S-polarized light (outputs of the sensors C2S and C3S) of the openings L2 and L3 for S-polarized light and an integrated signal obtained by integrating P-polarized light (outputs of the sensors C1P and C6P) of the openings L1 and L6 for P-polarized light are output from the signal integration unit D00 to the frequency separation unit D10. Subsequent processing from the frequency separation unit D10 is performed on the integrated signal received from the signal integration unit D00 in the same manner as in the first embodiment.

The example in FIG. 31 is an example of oblique illumination, but an appropriate combination of integrated signals differs for between, example, the oblique illumination and the epi-illumination, according to an incident angle of illumination light onto the sample surface.

In the embodiment, the same effects as those of the first embodiment can also be obtained. Further, a calculation load of the signal processing device D is further reduced and sequential processing is further smoothed by integrating detection signals. It is needless to say that the signal integration unit D00 in the embodiment can be applied not only to the first embodiment but also to the second embodiment.

### REFERENCE SIGNS LIST

1: sample
100: defect inspecting device
A: scattered light illumination system
B1 to Bn: scattered light detection system
B6″: bandpass filter (optical filter)
BS: illumination spot
D: signal processing device
D20: defect candidate detection unit
D30: feature calculation unit
D40: feature evaluation unit
D41, D42: input port
D43: output port
D50: determination unit
D60: defect feature evaluation instruction analysis
unit
Da: coordinate matching unit
E0 to E3: flag (evaluation data)
E30: monitor
F: differential interference detection system
G: differential interference illumination system
H1 to HN: low-frequency signal (low-frequency
component)
r1 to r3: region
Sig1 to SigN: high-frequency signal (high-frequency
component)
sr1, sr2: script
Tia: calculation data structure
T: script data structure
Th, Th_θ: threshold
α1 to αN: detection signal

1. A defect inspecting device comprising:
a scattered light illumination system configured to form an illumination spot on a sample surface;
a scattered light detection system configured to detect light from the illumination spot;
a signal processing device configured to process a detection signal output from the scattered light detection system; and
a monitor configured to display an output of the signal processing device, wherein
the signal processing device includes
a defect feature evaluation instruction analysis unit configured to analyze a defect determination script describing data processing related to evaluation of a defect candidate by using a predetermined region of an input and output buffer, which is a specific memory area, as an input port for inputting feature data of the defect candidate and an output port for outputting evaluation data of the defect candidate, configure, as a calculation data structure, a data structure having a structure in which a data input unit of the input and output buffer, an instruction using data input to the data input unit, and a data output unit of the input and output buffer that stores execution data of the instruction are associated with one another, and configure a script data structure including a plurality of the calculation data structures,
a defect candidate detection unit configured to detect the defect candidate based on the detection signal output from the scattered light detection system,
a feature calculation unit configured to calculate the feature data of the defect candidate based on the detection signal and input the calculated feature data to the input port,
a feature evaluation unit configured to calculate the evaluation data by sequentially executing, for each of the calculation data structures, processing of executing an instruction associated in the calculation data structure and storing an execution result in the data output unit, by using data of the data input unit associated in the calculation data structure, and
a determination unit configured to determine whether the defect candidate is a defect based on the evaluation data output from the output port.

2. The defect inspecting device according to claim 1, wherein
the calculation data structure is a binary tree structure.

3. The defect inspecting device according to claim 1, wherein
the feature calculation unit calculates feature data of roughness scattered light from the sample surface based on the detection signal, and inputs the feature data of the roughness scattered light to the input port together with the feature data of the defect candidate, and
the defect feature evaluation instruction analysis unit analyzes a defect determination script describing data processing related to evaluation of the feature data of the defect candidate and the feature data of the roughness scattered light to configure the script data structure.

4. The defect inspecting device according to claim 1, wherein
the defect candidate detection unit calculates a normalized signal obtained by normalizing a high-frequency component of a detection signal from the scattered light detection system based on a low-frequency component of the detection signal from the scattered light detection system, and sets the detection signal as the defect candidate when a magnitude of the normalized signal is larger than a threshold.

5. The defect inspecting device according to claim 1, wherein
the feature evaluation unit sequentially executes the instruction for each of the calculation data structures, calculates a similarity between a predetermined scattered light vector model and a feature data vector of a high-frequency component of a detection signal related to the defect candidate, and calculates the evaluation data indicating that the defect candidate is a defect when the similarity exceeds a threshold, and
the threshold varies depending on a type of the defect.

6. The defect inspecting device according to claim 5, wherein
the script data structure is different for each region of the sample surface.

7. The defect inspecting device according to claim 1, further comprising:
a differential interference illumination system configured to form an illumination spot on the sample surface with light having a wavelength different from a wavelength of light emitted from the scattered light illumination system; and
a differential interference detection system configured to detect light from the illumination spot formed by the differential interference illumination system, wherein
the scattered light detection system includes an optical filter configured to filter a wavelength of the differential interference illumination system,
the defect candidate detection unit detects a first defect candidate group based on a detection signal of the scattered light detection system and a second defect candidate group based on a detection signal of the differential interference detection system,
the signal processing device includes a coordinate matching unit configured to compare defect coordinates of the first defect candidate group with defect coordinates of the second defect candidate group and treat defect candidates having a deviation amount equal to or less than a set distance as the same defect candidate, and
the feature calculation unit calculates integrated feature data obtained by integrating first feature data related to the detection signal of the scattered light detection system and second feature data related to the detection signal of the differential interference detection system based on coordinate comparison data of the coordinate matching unit, and inputs the integrated feature data to the input port as the feature data.
